(19) United States
(12) Patent Application Publication
(10) Pub. No.: US 2024/0404891 A1
(43) Pub. Date: Dec. 5, 2024

(54) EPITAXY FAST RAMP TEMPERATURE CONTROL SYSTEMS AND PROCESSES

(71) Applicant: ASM IP Holding B.V., Almere (NL)

(72) Inventors: Junwei Su, Chandler, AZ (US); Shujin Huang, Phoenix, AZ (US); Kevin Eugene Quinn, Gilbert, AZ (US); Yang Wang, Chandler, AZ (US); Zhizhong Chen, Tempe, AZ (US); Chengzi Huang, Chandler, AZ (US)

(21) Appl. No.: 18/677,160

(22) Filed: May 29, 2024

Related U.S. Application Data
(60) Provisional application No. 63/470,004, filed on May 31, 2023.

(51) Int. Cl. H01L 21/66; H01L 21/324

(52) U.S. Cl. CPC H01L 22/12; H01L 21/324

(57) ABSTRACT

Substrate processing systems and methods include: (a) seating a substrate on a support; (b) optically measuring center substrate temperature using a first pyrometer; (c) optically measuring edge substrate temperature using a second pyrometer; and (d) determining an edge offset temperature between the edge substrate temperature and the center substrate temperature. Three temperature ramping steps are used to heat up the substrate for processing: two fast ramping steps and one slow ramping steps. After substrate processing, an initial, controlled cooling step is provided. During at least the second fast temperature ramping step, the slow temperature ramping step, the substrate processing step(s), and the initial controlled cooling step, heating of the substrate is controlled to place and/or hold the edge offset temperature within predetermined ranges in order to maintain uniform temperature and/or a desired temperature gradient across the substrate. Such systems and methods help avoid crystal defects (e.g., slip) and/or auto-doping.

### CROSS-REFERENCE TO RELATED APPLICATION(S)

This application claims the benefit of U.S. Provisional Application 63/470,004 filed on May 31, 2023, the entire contents of which are incorporated herein by reference.

### FIELD OF THE DISCLOSURE

The present disclosure relates generally to temperature control systems and methods. Some more particular aspects of this technology relate to controlling substrate temperature while depositing material layers onto substrates (e.g., during fabrication of semiconductor devices). In some examples of this technology, substrates will be processed under controlled temperature conditions in a manner to avoid crystallographic slip and/or auto-doping.

### BACKGROUND OF THE DISCLOSURE

Material layers are commonly deposited onto substrates during fabrication of semiconductor devices, such as during fabrication of integrated circuits and electronic devices. Material layer deposition is generally accomplished by supporting a substrate within a chamber arrangement, heating the substrate to a desired deposition temperature, and flowing one or more material layer precursors through the chamber arrangement and across the substrate. As the precursor flows across the substrate, the material layer progressively develops onto the surface of the substrate, typically according to the temperature of the substrate and environmental conditions within the chamber arrangement.

Atmospheric epitaxial silicon layer deposition using trichlorosilane (TCS) gas typically takes place at high temperatures (1050° C. to 1200° C.). During production of epitaxial silicon, however, it is very common that crystal line defects (e.g., crystallographic slip defects) will develop as the substrate is grown. Typical production processes seek to reduce the occurrence of crystal line defects by heating the workpieces at a slow rate to reduce thermal stress and maintain a constant temperature gradient across the substrate during the process. But because typical processing temperatures are quite high, the temperature ramping processes (e.g., heating up from a starting temperature to the processing temperature) may need to span hundreds of degrees (e.g., from approx. 650° C. to approx. 1200° C. for processing). Such large temperature differences and slow ramping rates make the ramping steps some of the most time consuming steps in some semiconductor processing. Manufacturers have worked to adjust their processing conditions in an effort to balance and optimize processing time vs. crystal defect production. Such methods, however, typically represent a tradeoff between temperature ramping rates and the generation of slip defects (and/or other crystallographic defects).

Other issues also may impact epitaxially grown crystal quality. For example, during high temperature epitaxial growth, dopants in substrates (e.g., boron, phosphorus, etc.) can evaporate/migrate from the substrates (e.g., from the bottom of silicon wafers) and incorporate (re-deposit) into the epitaxial layers being formed at the top of the substrate. This phenomenon is known as “auto-doping.” Such auto-doping can be particularly severe when forming heavily doped silicon wafers. Auto-doping can result in undesired resistivity non-uniformity over the substrate area and volume and degrade product performance.

Conventional semiconductor production systems and methods have generally been acceptable for their intended purpose, but these conventional systems and methods generally represent a tradeoff between the competing interests of process speed (e.g., production cycle times) and defect formation/product degradation (e.g., crystallographic slip, auto-doping, etc.). Thus, there remains a need in the art for improved substrate processing conditions that will enable fast processing times (e.g., with reduced temperature ramping times) while still producing high quality crystal products in high volumes (e.g., forming crystal products having reduced defect production, such as crystallographic slip and/or auto-doping effects).

### SUMMARY OF THE DISCLOSURE

Substrate processing methods are provided. Such methods may include: (a) seating a substrate on a substrate support; (b) measuring a center substrate temperature using a first pyrometer configured to optically measure temperature of the substrate at a center location of the substrate; (c) measuring an edge substrate temperature using a second pyrometer configured to optically measure temperature of the substrate at an edge location of the substrate; and (d) determining an edge offset temperature between the edge substrate temperature and the center substrate temperature. These measurements may be made repeatedly throughout at least some and potentially all of the process steps. The methods further include: (e) during a first temperature ramping step, increasing substrate temperature from a first temperature to a second temperature at a first fast temperature ramping rate; (f) during a second temperature ramping step, increasing substrate temperature from the second temperature to a third temperature at a second fast temperature ramping rate, wherein the second fast temperature ramping rate may be the same as or different from the first fast temperature ramping rate, and wherein during the second temperature ramping step, heating of the substrate is controlled to place and/or hold the edge offset temperature within a first predetermined range; and (g) during a third temperature ramping step, increasing substrate temperature from the third temperature to a fourth temperature (e.g., a final processing temperature) at a slow temperature ramping rate, wherein during the third temperature ramping step, heating of the substrate is controlled to place and/or hold the edge offset temperature within a second predetermined range, wherein the second predetermined range may be the same as or different from the first predetermined range.

In at least some examples of this technology, substrate processing methods of the types described above may be performed in a chamber arrangement that includes: (i) a chamber body having an upper wall and a lower wall, (ii) the substrate support arranged within an interior of the chamber body and supported for rotation about a rotation axis, (iii) an upper heater element array supported above the upper wall of the chamber body, wherein heater elements of the upper heater element array include at least a first heating zone and a second heating zone, (iv) a first pyrometer supported above the upper heater element array, optically coupled to the interior of the chamber body, and configured to optically measure a center substrate temperature, (v) a second pyrometer supported above the upper heater element array, optically coupled to the interior of the chamber body, and configured to optically measure an edge substrate temperature, and (vi) a control system to control power applied to the heater elements of the upper heater element array.

In addition to one or more of the features described above, or as an alternative, further examples of methods in accordance with this technology may include, after the third temperature ramping step: (i) flowing a material layer precursor across the substrate; and (ii) depositing a material layer onto the substrate using the material layer precursor, wherein during the flowing and depositing, heating of the substrate is controlled to place and/or hold the edge offset temperature within a third predetermined range, and wherein the third predetermined range may be the same as or different from the second predetermined range.

In addition to one or more of the features described above, or as an alternative, further examples of methods in accordance with this technology may include measuring an intermediate substrate temperature using a third pyrometer configured to optically measure temperature of the substrate at an intermediate location on the substrate between the center location and the edge location (e.g., halfway between the center and edge), wherein at least during the material layer depositing step, heating of the substrate is controlled to place and/or hold the intermediate substrate temperature within a predetermined temperature range from the center substrate temperature and/or within a predetermined temperature range from the edge substrate temperature.

In addition to one or more of the features described above, or as an alternative, further examples of methods in accordance with this technology may include cooling the substrate to a first cooled temperature (e.g., after processing, such as the layer deposition step(s)), wherein during the cooling, heating of the substrate is controlled: (i) to place and/or hold the edge offset temperature within a controlled temperature differential range, and (ii) to cool the substrate at a cooling rate that is slower than a free fall cooling rate. Additionally, in such methods, after the substrate reaches the first cooled temperature, further cooling of the substrate may take place using a free fall cooling technique.

In addition to one or more of the features described above, or as an alternative, further examples of methods in accordance with this technology may include, during the first temperature ramping step, controlled heating of the substrate to place and/or hold the edge offset temperature within an initial temperature differential range, wherein the initial temperature differential range is wider than the first predetermined range used in the second temperature ramping step.

In addition to one or more of the features described above, or as an alternative, further examples of methods in accordance with this technology may include measuring an intermediate substrate temperature using a third pyrometer configured to optically measure temperature of the substrate at an intermediate location on the substrate between the center location and the edge location, wherein during the second temperature ramping step and/or during the third temperature ramping step, heating of the substrate is controlled to place and/or hold the intermediate substrate temperature within a first predetermined temperature range from the center substrate temperature.

In addition to one or more of the features described above, or as an alternative, further examples of methods in accordance with this technology may include measuring an intermediate substrate temperature using a third pyrometer configured to optically measure temperature of the substrate at an intermediate location on the substrate between the center location and the edge location, wherein during the second temperature ramping step and/or during the third temperature ramping step, heating of the substrate is controlled to place and/or hold the intermediate substrate temperature within a first predetermined temperature range from the edge substrate temperature.

Additional aspects of this technology relate to systems (e.g., chamber arrangements and/or other substrate processing systems) for holding a substrate and performing one or more of the processes described above. Such systems may include a programmable controller (e.g., a proportional-integral-derivative (PID) controller) that receives optical temperature input data from the pyrometers and uses that data to control at least substrate center temperature, substrate edge temperature, and edge offset temperature to be within desired ranges (within desired ranges of temperature “set points” for the center, edge, and/or edge offset temperatures) during one or more of the second temperature ramping step, the third temperature ramping step, the wafer processing step(s) (e.g., layer deposition steps), and/or the initial controlled cooling step. The programmable controller also may use that data to control at least substrate center temperature, substrate edge temperature, and edge offset temperature to be within desired ranges of “set points” during the first temperature ramping step. Additionally or alternatively, the programmable controller may receive optical temperature input data from an intermediate pyrometer and use that data to control one or more of the intermediate substrate temperature, the temperature difference between the substrate's center and intermediate locations, and the temperature difference between the substrate's edge and intermediate locations. The programmable controller may selectively apply power to individual heater elements of one or more heater arrays to selectively and controllably heat or cool different areas of the substrate to place and/or hold the center, edge, and/or intermediate substrate temperatures and/or temperature differences within desired ranges of predetermined set points.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a semiconductor processing system including a chamber arrangement in accordance with the present disclosure, showing a precursor delivery arrangement connected to an exhaust arrangement by a chamber arrangement;

FIG. 2 is a schematic view of the semiconductor processing system of FIG. 1 according to an example of the present disclosure, showing the precursor delivery arrangement providing a precursor to the chamber arrangement and the exhaust arrangement receiving a flow of residual precursor and/or reaction products issued by the chamber arrangement;

FIGS. 3 and 4 are schematic side and top views of the chamber arrangement of FIG. 1 according to a first example of the present disclosure, showing a pyrometer and a thermocouple operatively connected to an upper heater element array and a lower heater element array of the chamber arrangement according to the first example of the present disclosure;

FIGS. 5 and 6 are schematic side and top views of the chamber arrangement of FIG. 1 according to a second example of the present disclosure, showing a pyrometer and thermocouples operatively connected to an upper heater element array and a lower heater element array of the chamber arrangement according to the second example of the present disclosure;

FIGS. 7 and 8 are schematic side and top views of the chamber arrangement of FIG. 1 according to a third example of the present disclosure, showing two pyrometer and a thermocouple operatively connected to an upper heater element array and a lower heater element array of the chamber arrangement according to the third example of the present disclosure;

FIGS. 9 and 10 are schematic side and top views of the chamber arrangement of FIG. 1 according to a fourth example of the present disclosure, showing three pyrometer and a thermocouple operatively connected to an upper heater element array and a lower heater element array of the chamber arrangement according to the fourth example of the present disclosure;

FIGS. 11-13 are block diagrams of an example of a material layer deposition method in accordance with the present disclosure, showing operations of the method according to an illustrative and non-limiting example of the present disclosure;

FIG. 14A provides a flow diagram of methods of processing substrates in accordance with at least some examples of the present disclosure;

FIG. 14B provides an example of time/temperature changes during methods of processing substrates in accordance with at least some examples of the present disclosure; and

FIG. 15 provides a flow diagram of temperature control processes in accordance with some examples of this disclosure.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION

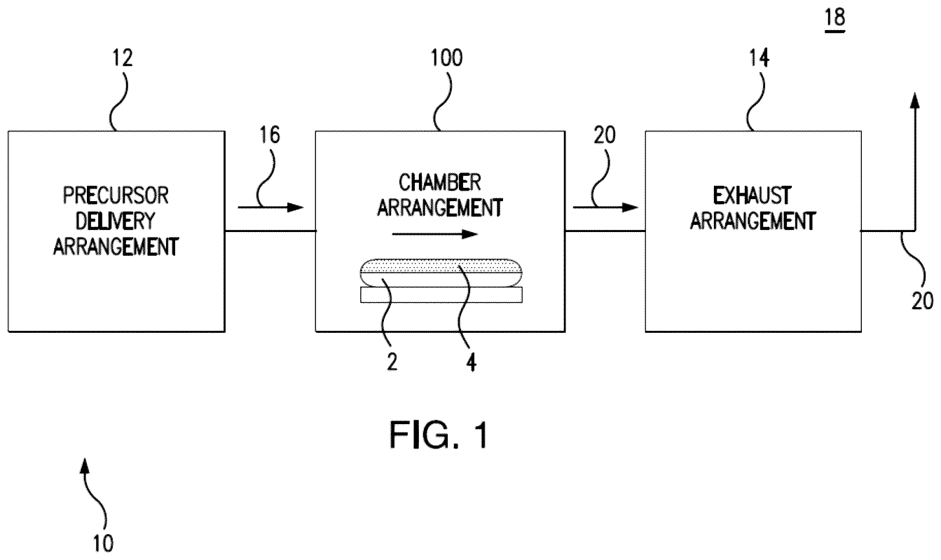

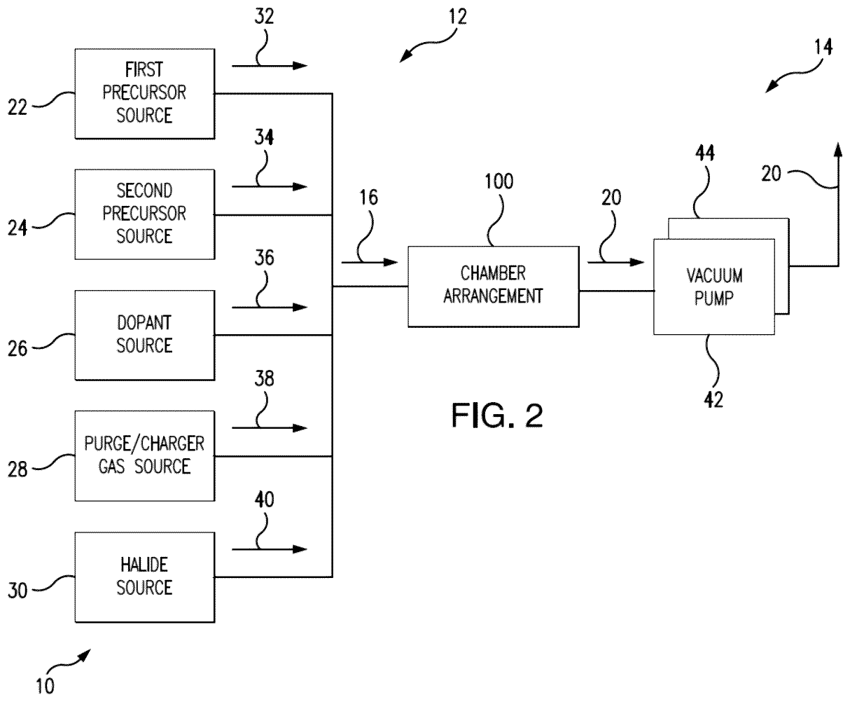

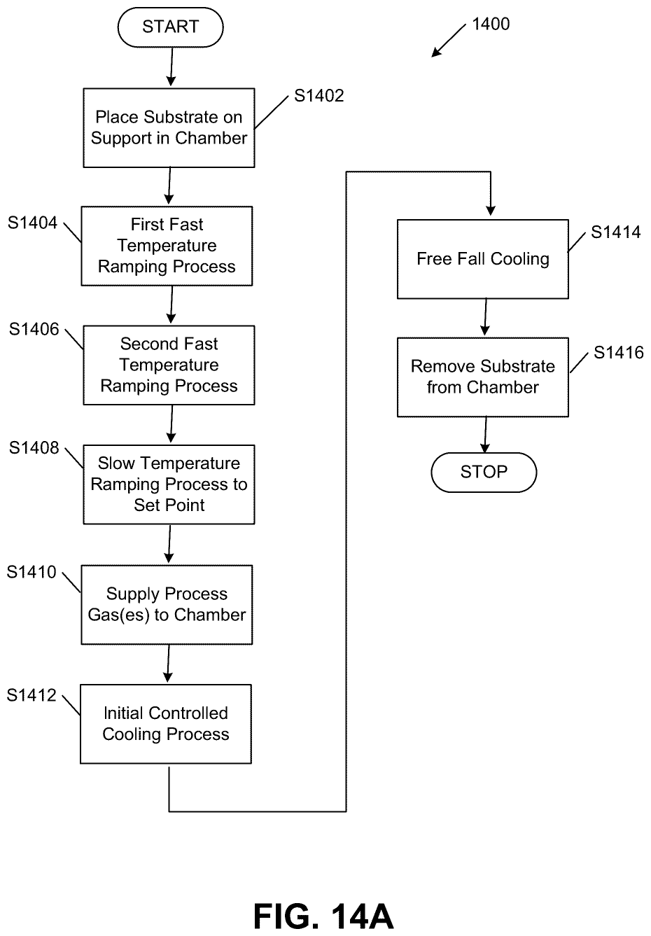

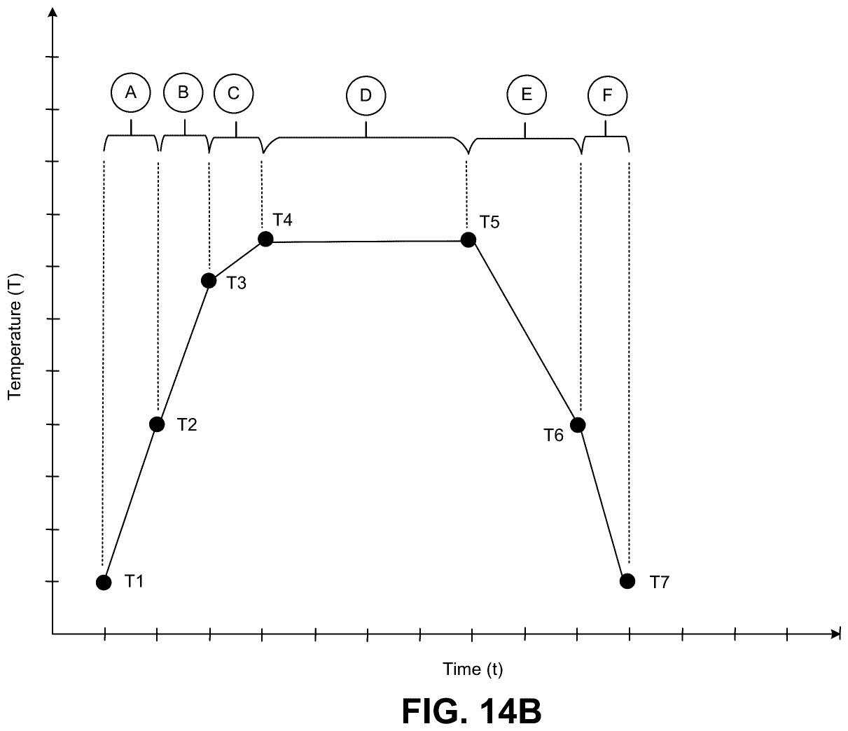

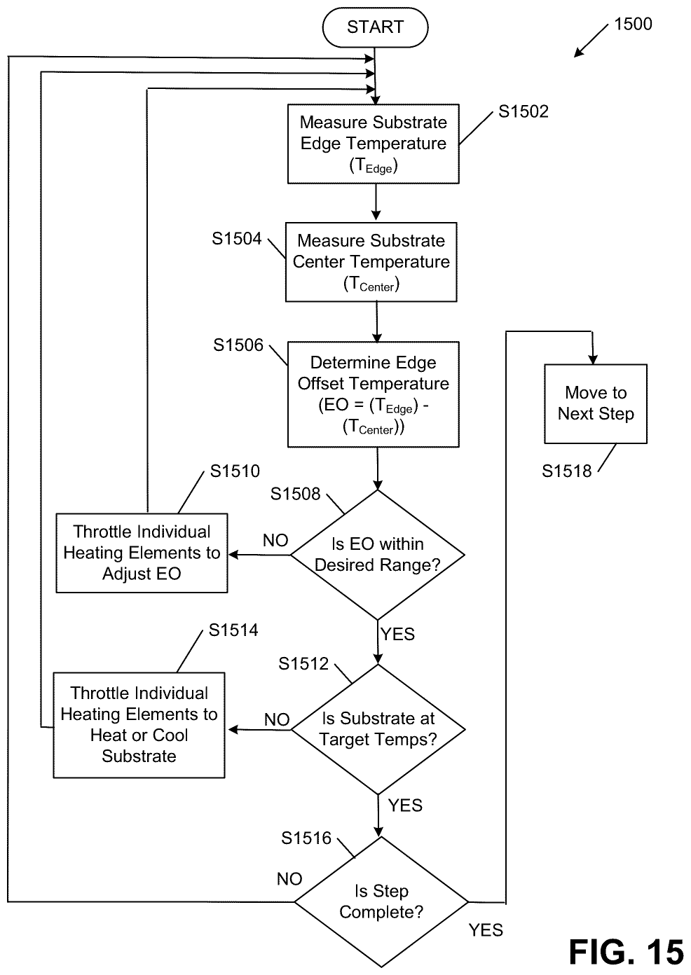

Reference will now be made to the drawings wherein like reference numerals identify similar structural features or aspects of the subject disclosure. For purposes of explanation and illustration, and not limitation, a partial view of an example of a chamber arrangement in accordance with the present disclosure is shown in FIG. 1 and is designated generally by reference character 100. Other examples of chamber arrangements, semiconductor processing systems, and methods of depositing material layers onto substrates in accordance with the present disclosure, or aspects thereof, are provided in FIGS. 2-13, as will be described. The systems and methods of the present disclosure can be used to control one or more of substrate temperature during the deposition of material layers onto substrates, such as during the deposition of epitaxial material layers onto substrates during the fabrication of semiconductor devices, though the present disclosure is not limited to epitaxial material layers or to the fabrication of any particular type of semiconductor device. FIGS. 14A-15 provide information relating to some example substrates processing methods that may use at least some of the systems, e.g., of FIGS. 1, 2, and 7-10.

With reference to FIG. 1, a semiconductor processing system 10 is shown. The semiconductor processing system 10 includes a precursor delivery arrangement 12, the chamber arrangement 100, and an exhaust arrangement 14. The precursor delivery arrangement 12 is connected to the chamber arrangement 100 and is configured to provide a precursor 16 to the chamber arrangement 100. The chamber arrangement 100 is connected to the exhaust arrangement 14 and is configured to deposit a material layer 4 onto a substrate 2 supported within the chamber arrangement 100 using the precursor 16. The exhaust arrangement 14 is in fluid communication with the environment 18 external to the semiconductor processing system 10 and is configured to communicate a flow of residual precursor and/or reaction products 20 to the environment 18 external to the semiconductor processing system 10.

As used herein, the term “substrate” may refer to any underlying material or materials that may be used, or upon which, a device, a circuit, or a film may be formed. The “substrate” may be continuous or non-continuous; rigid or flexible; solid or porous. The substrate may be in any form such as a powder, a plate, or a workpiece. Substrates in the form of a plate may include wafers, e.g., 300-millimeter silicon wafers, in various shapes and sizes. Substrates may be made from materials such as silicon, silicon germanium, silicon oxide, gallium arsenide, gallium nitride, and silicon carbide by way of non-limiting example. A continuous substrate may extend beyond the bounds of a process chamber where a deposition process occurs and may move through the process chamber such that the process continues until the end of the substrate is reached. A continuous substrate may be supplied from a continuous substrate feeding system, enabling manufacture and output of the continuous substrate in any appropriate form.

With reference to FIG. 2, the precursor delivery arrangement 12 and the exhaust arrangement 14 are shown. The precursor delivery arrangement 12 includes a first precursor source 22, a second precursor source 24, and a dopant source 26. The precursor delivery arrangement 12 also includes a purge/carrier gas source 28 and a halide source 30. The first precursor source 22 is connected to the chamber arrangement 100, includes a silicon-containing precursor 32, and is configured to provide a flow of the silicon-containing precursor 32 to the chamber arrangement 100. Non-limiting examples of suitable silicon-containing precursors include chlorinated silicon-containing precursors, such as dichlorosilane (H₂SiCl₂) and trichlorosilane (HCl₃Si), and non-chlorinated silicon-containing precursors, such as silane (SiH₄) and disilane (Si₂H₆).

The second precursor source 24 is connected to the chamber arrangement 100, includes a germanium-containing precursor 34, and is configured to provide a flow of the germanium-containing precursor 34 to the chamber arrangement 100. Examples of suitable germanium-containing precursors include germane (GeH₄). The dopant source 26 is similarly connected to the chamber arrangement 100, includes a dopant-containing precursor 36, and is further configured to provide a flow of the dopant-containing precursor 36 to the chamber arrangement 100. In certain examples the dopant-containing precursor 36 may include phosphorous (P). It is also contemplated that the dopant-containing precursor 36 may include boron (B) and/or arsenic (As) and remain within the scope of the present disclosure.

The purge/carrier gas source 28 is further connected to the chamber arrangement 100, includes a purge/carrier gas 38, and is additionally configured to provide a flow of the purge/carrier gas 38 to the chamber arrangement 100. In this respect the purge/carrier gas source 28 may be configured to employ the purge/carrier gas 38 to carry one or more of the silicon-containing precursor 32, the germanium-containing precursor 34, and/or the dopant-containing precursor 36 into the chamber arrangement 100. Examples of suitable purge/carrier gases include hydrogen (H₂) gas, inert gases such as argon (Ar) gas or helium (He) gas, and mixtures thereof.

The halide source 30 is connected to the chamber arrangement 100, includes a halide-containing material 40, and is configured to provide a flow of the halide-containing material 40 to the chamber arrangement 100. The halide-containing material 40 may be co-flowed with the precursor 16. The halide-containing material 40 may be flowed independently from the precursor 16, such as to provide a purge and/or to remove condensate from within the chamber arrangement 100. Examples of suitable halides include chlorine (Cl), e.g., chlorine (Cl₂) gas and hydrochloric (HCl) acid, as well as fluorine (F), e.g., fluorine (F₂) gas and hydrofluoric (HF) acid.

The exhaust arrangement 14 is configured to evacuate the chamber arrangement 100 and in this respect may include one or more vacuum pump 42 and/or an abatement apparatus 44. The one or more vacuum pumps 42 may be connected to the chamber arrangement 100 and configured to control pressure within the chamber arrangement 100. The abatement apparatus 44 may be connected to the one or more vacuum pumps 42 and configured to process the flow of residual precursor and/or reaction products 20 issued by the chamber arrangement 100. It is contemplated that the exhaust arrangement 14 may be configured to maintain environmental conditions within the chamber arrangement 100 suitable for atmospheric deposition operations, such as pressures between about 500 torr and about 760 torr, such as during the deposition of epitaxial material layers including silicon during atmospheric pressure techniques. The exhaust arrangement 14 may also be configured to maintain environmental conditions within the chamber arrangement 100 suitable for reduced pressure deposition operations, such as pressures between about 3 torr and about 500 torr, such as during the deposition of epitaxial material layers including using reduced pressure techniques.

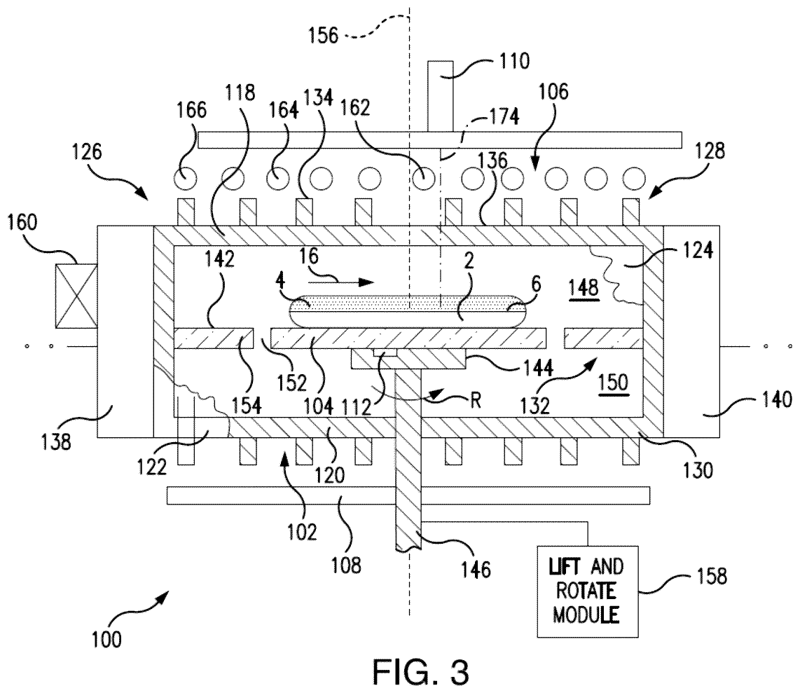

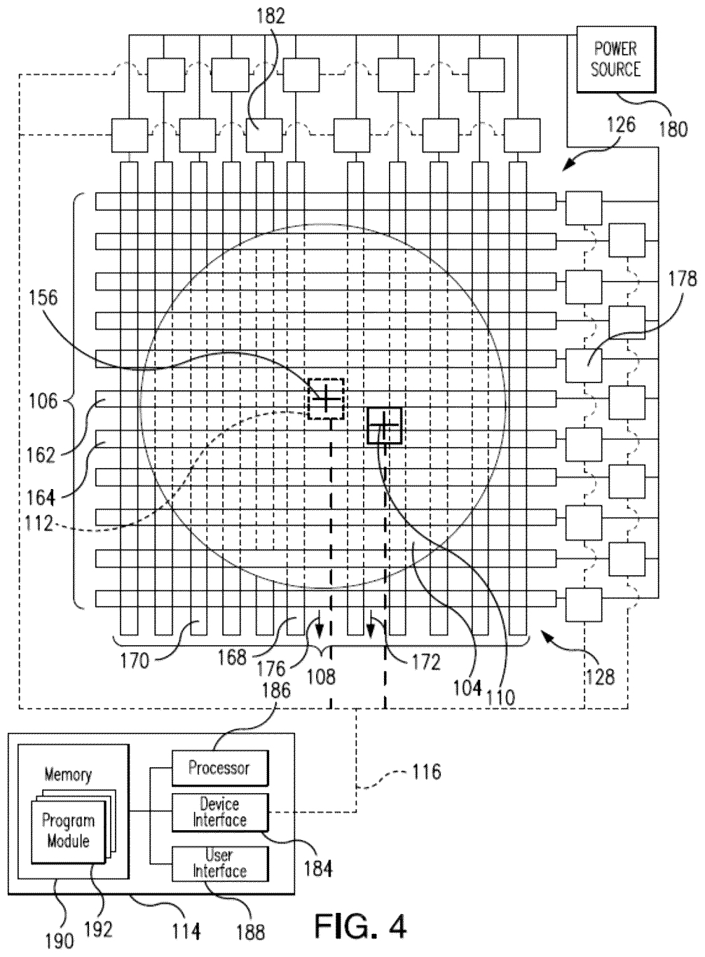

With reference to FIG. 3, the chamber arrangement 100 is shown. The chamber arrangement 100 includes a chamber body 102 and a substrate support 104. The chamber arrangement 100 also includes an upper heater element array 106 and a lower heater element array 108. The chamber arrangement 100 further includes a pyrometer 110, a thermocouple 112, a controller 114 (shown in FIG. 4), and a wired or wireless link 116 (shown in FIG. 4). Although a specific arrangement is shown and described herein, it is to be understood and appreciated that the chamber arrangement 100 may include other elements and/or omit elements shown and described herein and remain within the scope of the present disclosure.

The chamber body 102 is configured to flow the precursor 16 across the substrate 2 and has an upper wall 118, a lower wall 120, a first sidewall 122, and a second sidewall 124. The upper wall 118 extends longitudinally between an injection end 126 and a longitudinally opposite exhaust end 128 of the chamber body 102, is supported horizontally relative to gravity, and is formed from a transmissive material 130. The lower wall 120 is below and parallel relative to the upper wall 118 of the chamber body 102, is spaced apart from the upper wall 118 by an interior 132 of the chamber body 102, and is also formed from the transmissive material 130. The first sidewall 122 longitudinally spans the injection end 126 and the exhaust end 128 of the chamber body 102, extends vertically between the upper wall 118 and the lower wall 120 of the chamber body 102, and is formed from the transmissive material 130. The second sidewall 124 is parallel to the first sidewall 122, is laterally opposite and spaced apart from the first sidewall 122 by the interior 132 of the chamber body 102, and is further formed from the transmissive material 130. In certain examples, the transmissive material 130 may include a ceramic material such as sapphire or quartz. In accordance with certain examples, the chamber body 102 may include a plurality of external ribs 134. The plurality of external ribs 134 may extend laterally about an exterior 136 of the chamber body 102 and be longitudinally spaced between the injection end 126 and the exhaust end 128 of the chamber body 102. In certain examples, the one or more of the walls 116-122 may be substantially planar. In accordance with certain examples, one or more of the walls 116-122 may be arcuate or dome-like in shape. It is also contemplated that, in accordance with certain examples, the chamber body 102 may include no ribs.

An injection flange 138 and an exhaust flange 140 may be connected to the injection end 126 and the exhaust end 128, respectively, of the chamber body 102. The injection flange 138 may fluidly couple the precursor delivery arrangement 12 (shown in FIG. 1) to the interior 132 of the chamber body 102 and be configured to provide the precursor 16 to the interior 132 of the chamber body 102. The exhaust flange 140 may fluidly couple the interior 132 of the chamber body 102 to the exhaust arrangement 14. The exhaust flange 140 may be configured to communicate the residual precursor and/or reaction products 20 (shown in FIG. 1) issued by the chamber arrangement 100 during deposition of the material layer 4 onto the substrate 2. In this respect the chamber body 102 may have a cold wall, cross-flow reactor configuration.

A divider 142, a support member 144, and a shaft member 146 may be arranged within the interior 132 of the chamber body 102. The divider 142 may be fixed within the interior 132 of the chamber body 102 and divide the interior 132 of the chamber body 102 into an upper chamber 148 and a lower chamber 150. The divider 142 may further define an aperture 152 therethrough, the aperture 152 fluidly coupling the upper chamber 148 of the chamber body 102 to the lower chamber 150 of the chamber body 102. The divider 142 may be formed from an opaque material 154. The opaque material 154 may include silicon carbide.

The substrate support 104 may be configured to seat thereon the substrate 2 and supported at least partially within the aperture 152 for rotation R about a rotation axis 156. The substrate support 104 may seat the substrate 2 such that a radially-outer peripheral of the substrate 2 abuts the substrate support 104 while a radially-inner central portion of the substrate 2 is spaced apart from the substrate support 104. The support member 144 may be arranged below the substrate support 104 and along the rotation axis 156. The support member 144 may be further arranged within the lower chamber 150 of the chamber body 102, and fixed in rotation relative to the substrate support 104 about the rotation axis 156 for rotation with the substrate support 104. The substrate support 104 may be formed from an opaque material, such as the opaque material 154 or a graphite material. The support member 144 may be formed from a transmissive material, such as the transmissive material 130.

The shaft member 146 may be arranged along the rotation axis 156 and fixed in rotation relative to the support member 144 about the rotation axis 156. The shaft member 146 may also extend through the lower chamber 150 of the chamber body 102 and through lower wall 120 of chamber body 102. The shaft member 146 may further operably connect a lift and rotate module 158 to the substrate support 104, the lift and rotate module 158 in turn may be configured to rotate R the substrate support 104 and the substrate 2 about the rotation axis 156 during deposition of the material layer 4 onto an upper surface 6 of the substrate 2. The lift and rotate module 158 may further cooperate with a gate valve 160 and a lift pin arrangement to seat and unseat the substrate 2 from the substrate support 104, such as through a substrate handling robot arranged within a cluster-type platform in selective communication with the interior 132 of the chamber body 102 through the gate valve 160. In certain examples the shaft member 146 may be formed from a transmissive material, such as the transmissive material 130.

The upper heater element array 106 is configured to heat the substrate 2 and/or the material layer 4 during deposition onto the substrate 2 by radiantly communicating heat into the upper chamber 148 of the chamber body 102. In this respect the upper heater element array 106 may include a first upper heater element 162, a second upper heater element 164, and at least one third upper heater element 166. The first upper heater element 162 may include a linear filament and a quartz tube enclosing the linear filament and/or may include one or more bulb or lamp-type heater elements. The first upper heater element 162 may be supported above the upper wall 118 of the chamber body 102, extend laterally between the first sidewall 122 and the second sidewall 124 of the chamber body 102, and may further overlay the substrate support 104. The second upper heater element 164 and the at least one third upper heater element 166 may be similar to the first upper heater element 162, may additionally be longitudinally spaced apart from the first upper heater element 162, and may further be longitudinally spaced apart from the rotation axis 156. The second upper heater element 164 may further overlay (e.g., intersect) a peripheral edge of the substrate 2. The at least one third upper heater element 166 may overlay the divider 142. In certain examples, the upper heater element array 106 may include eleven (11) or twelve (12) upper heater elements. Each upper heater element of the upper heater element array 106 may be longitudinally spaced apart from one another above the upper wall 118 of the chamber body 102 between the injection end 126 and the exhaust end 128 of the chamber body 102.

With reference to FIG. 4, the lower heater element array 108 is similar to the upper heater element array 106 and is also configured to heat the substrate 2 (shown in FIG. 1) and/or the material layer 4 (shown in FIG. 1) during deposition onto the substrate 2. In this respect the lower heater element array 108 may be configured to communicate radiant heat into the lower chamber 150 (shown in FIG. 3) of the chamber body 102 (shown in FIG. 3) to the substrate support 104 (shown in FIG. 3) and the divider 142 (shown in FIG. 3). The substrate support 104 and the divider 142 may in turn heat the substrate 2 by conducting the heat through the bulk material forming the substrate support 104 and the divider 142, radiant heat communicated into the lower chamber 150 by the lower heater element array 108 thereby being conducted to the substrate 2. The lower heater element array 108 may include a first lower heater element 168 and at least one second lower heater element 170.

The first lower heater element 168 is similar to the first upper heater element 162 and is additionally supported below the lower wall 120 (shown in FIG. 3) of the chamber body 102 (shown in FIG. 3). The first lower heater element 168 further extends longitudinally between the injection end 126 (shown in FIG. 3) and the exhaust end 128 (shown in FIG. 3) of the chamber body 102. The first lower heater element 168 may further be substantially orthogonal relative to the first upper heater element 162 of the upper heater element array 106. The at least one second lower heater element 170 may be parallel to the first lower heater element 168 and laterally spaced apart from the first lower heater element 168 below the lower wall 130 (shown in FIG. 3) of the chamber body 102. In certain examples, the first lower heater element 168 may underlie the substrate support 104. In accordance with certain examples, the at least one second lower heater element 170 may underlie the divider 142 (shown in FIG. 3). It is also contemplated that, in accordance with certain examples, the lower heater element array 108 may include eleven (11) or twelve (12) lower heater elements each laterally spaced apart from one another below the lower wall 120 of the chamber body 102.

The pyrometer 110 is configured to acquire an optical temperature measurement 172 using electromagnetic radiation emitted by the substrate 2 (shown in FIG. 1) and/or the material layer 4 (shown in FIG. 1). In this respect the pyrometer 110 is supported above the upper wall 118 (shown in FIG. 3) of the chamber body 102 (shown in FIG. 3) and is arranged along an optical axis 174 (shown in FIG. 3). More specifically, the pyrometer 110 is supported above the upper heater element array 106 and arranged longitudinally between the injection end 126 and the exhaust end 128 of the chamber body 102 such that the optical axis 174 may extend between the first upper heater element 162 and the second upper heater element 164. The optical axis 174 may further intersect the substrate support 104. The optical axis 174 may intersect the substrate 2 when seated on the substrate support 104, the optical temperature measurement 172 thereby acquired directly from the upper surface 6 of the substrate 2 and/or the material layer 4 during deposition onto the substrate 2 by pyrometer 110. In certain examples, the optical axis 174 may be coaxial with the rotation axis 156. In accordance with certain examples, the pyrometer 110 may be at least one of longitudinally offset and/or laterally offset from the rotation axis 156, e.g., radially offset from the rotation axis 156. As will be appreciated by those of skill in the art in view of the present disclosure, offsetting the optical axis 174 from the rotation axis 156 may facilitate packaging the pyrometer 110 above the chamber body 102. Examples of suitable pyrometers include OR400M optical infrared pyrometers, available from the Advanced Energy Corporation of Denver, Colorado.

The thermocouple 112 may be configured to acquire temperature of the substrate support 104 and provide a tactile temperature measurement 176 indicative of temperature of the substrate support 104. In this respect the thermocouple 112 may be arranged within the interior 132 (shown in FIG. 3) of the chamber body 102 (shown in FIG. 3). More specifically, the thermocouple 112 may be arranged within the lower chamber 150 (shown in FIG. 3) of the chamber body 102 and fixed in rotation R relative to the substrate support 104. Specifically, the thermocouple 112 may be in intimate mechanical contact (e.g., abut) contact with a lower surface of the substrate support 104. The thermocouple 112 may be arranged along the rotation axis 156. The thermocouple 112 may be offset from the rotation axis 156, for example radially offset from the rotation axis 156, such that the thermocouple 112 underlies the pyrometer 110, potentially improving accuracy of either (or both) the optical temperature measurement 172 provided by the pyrometer 110 and a tactile temperature measurement 176 provided by the thermocouple 112. Examples of suitable thermocouples includes those shown and described in U.S. Pat. No. 7,874,726 B2 to Jacobs et al, issued Jan. 25, 2011, the contents of which is incorporated herein by reference in its entirety.

The controller 114 is connected to the upper heater element array 106 and the lower heater element array 108. In this respect the wired or wireless link 116 may connect the controller 114 to the upper heater element array 106 and the lower heater element array 108. In certain examples one or more upper silicon controlled rectifier (SCR) devices 178 may couple the controller 114 to the upper heater element array 106. In accordance with certain examples, a singular one of the one or more upper SCR devices 178 couple each of the upper heater elements of the upper heater element array 106 to both the controller 114 and a power source 180, the controller 114 thereby having discrete control over power applied to each of the upper heater elements of the upper heater element array 106. The lower heater element array 108 may be similarly throttled, one or more lower SCR devices 182 coupling the controller 114 to the lower heater elements of the lower heater element array 108. The one or more lower SCR devices 182 may include a singular lower SCR device coupling each of the lower heater elements of the lower heater element array 108 to both the controller 114 and the power source 180 to provide discrete control over power applied to each of the lower heater elements of the lower heater element array 108.

It is contemplated that the controller 114 be connected to both the pyrometer 110 and the thermocouple 112, for example, by the wired or wireless link 116. In this respect the controller 114 may operatively connect the pyrometer 110 to the upper heater element array 106, and power applied to (and thereby radiant heat output from) the upper heater element array 106 may be throttled according to the optical temperature measurement 172 provided to the controller 114 by the pyrometer 110. The controller 114 may also operatively connect the thermocouple 112 to the lower heater element array 108, and power applied to (and thereby radiant heat output from) the lower heater element array 108 may be throttled by the tactile temperature measurement 176 provided to the controller 114 by the thermocouple 112.

As will be appreciated by those of skill in the art in view of the present disclosure, throttling heat output of the upper heater element array 106 using the pyrometer 110 and throttling heat output of the lower heater element array 108 may limit (or eliminate) oscillation in heating of substrate 2 that could otherwise be associated with lag in arrival of heat from the lower heater element array 108 at the substrate 2 through the thermal mass of the substrate support 104. In certain examples, heat output of the upper heater element array 106 may be exclusively throttled using the optical temperature measurement 172 provided by the pyrometer 110, and heat output of the lower heater element array 108 may be exclusively throttled by the tactile temperature measurement 176 provided by the thermocouple 112. It is also contemplated that hybrid throttling schemes may be employed, e.g., with weighting assignments, and remain within the scope of the present disclosure.

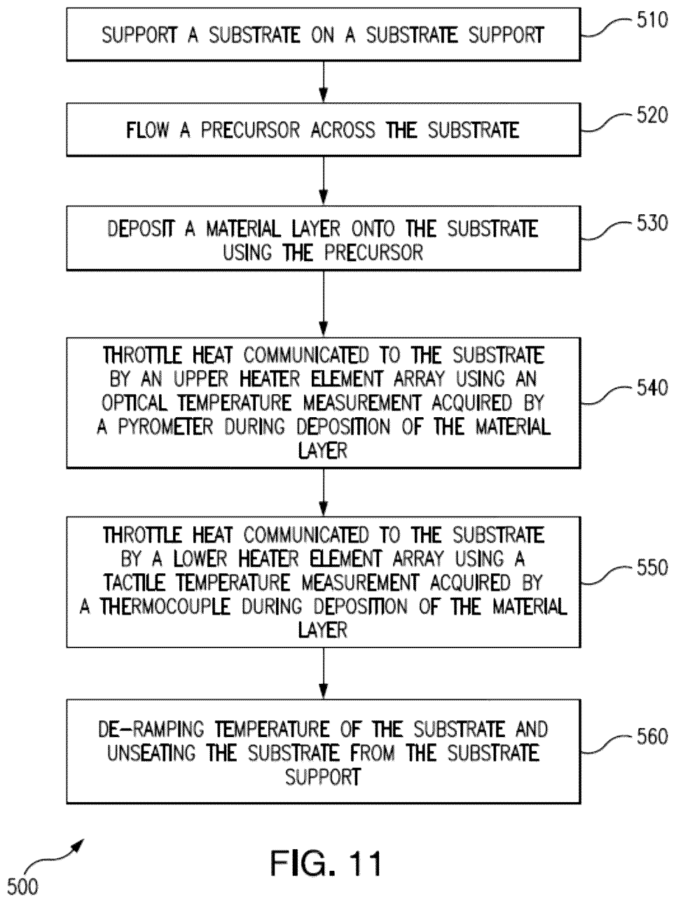

In the illustrated example the controller 114 includes a device interface 184, a processor 186, a user interface 188, and a memory 190. The device interface 184 connects the processor 186 to the wired or wireless link 116. The processor 186 is operably connected to the user interface 188 (e.g., to receive user input and/or provide user output therethrough) and is disposed in communication with the memory 190. The memory 190 includes a non-transitory machine-readable medium having a plurality of program modules 192 recorded thereon containing instructions that, when read by the processor 186, cause the processor 186 to execute certain operations. Among the operations are operations of a material layer deposition method 500 (shown in FIG. 11) as well as other methods, as will be described. As will be appreciated by those of skill in the art in view of the present disclosure, the controller 114 may have a different arrangement in other examples and remain within the scope of the present disclosure.

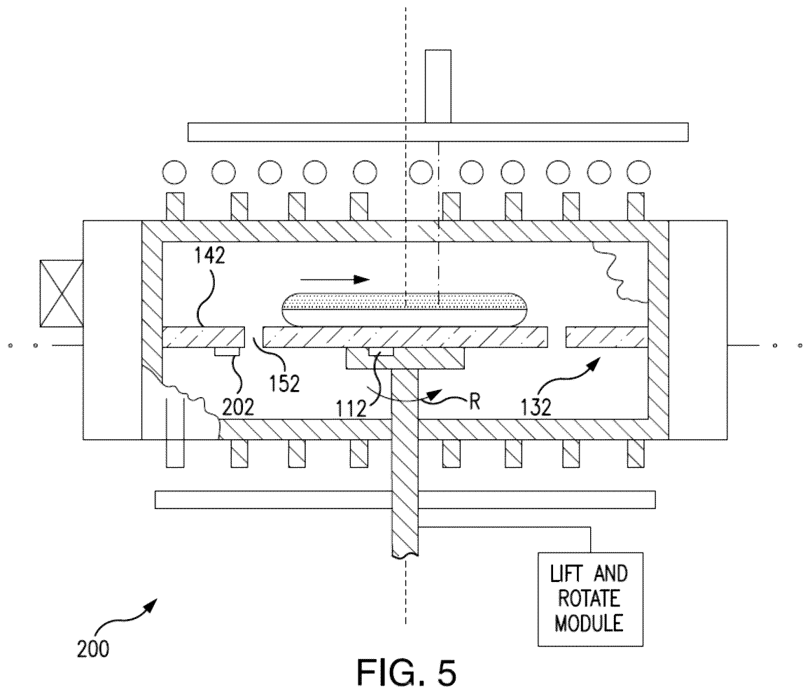

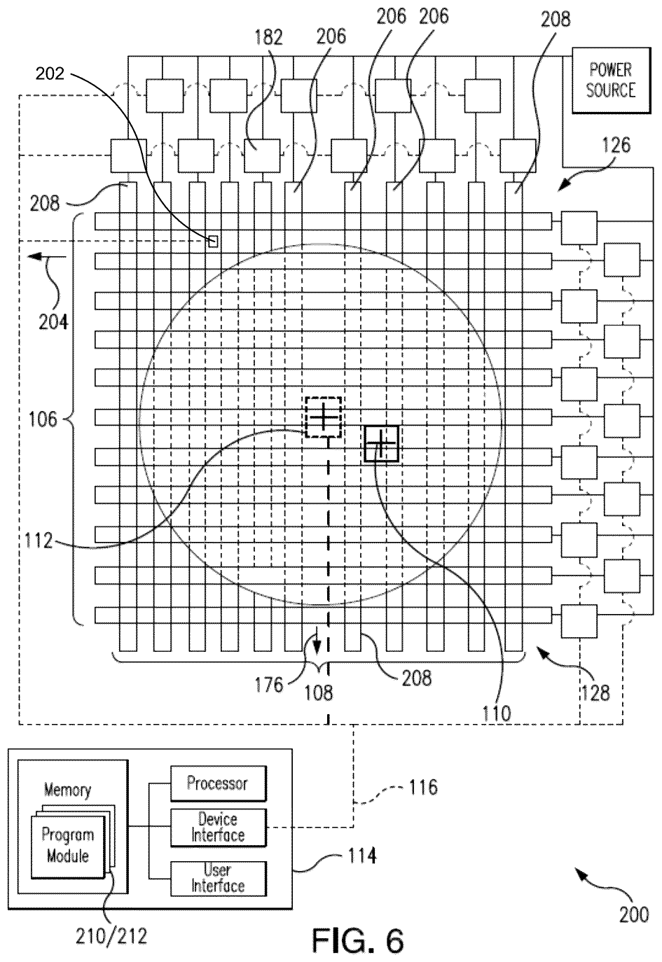

With reference to FIGS. 5 and 6, a chamber arrangement 200 is shown. The chamber arrangement 200 is similar to the chamber arrangement 100 (shown in FIG. 1) and additionally includes a static thermocouple 202, the thermocouple 112 being a rotating thermocouple 112. The static thermocouple 202 is arranged within the interior 132 of chamber body 102 and is fixed relative to the divider 142. More specifically, the static thermocouple 202 is arranged within an interior of the divider 142, is connected to the controller 114, and is configured to provide a second tactile temperature measurement 204 (shown in FIG. 6) to the controller 114. The static thermocouple 202 may be connected to the controller 114 by the wired or wireless link 116, the wired or wireless link 116 in turn communicating the second tactile temperature measurement 204 to the controller 114. In certain examples, the static thermocouple 202 may be one of a plurality of static thermocouples fixed on or within the interior of the divider 142 and distributed circumferentially about the aperture 152.

In the illustrated example the controller 114 may be configured to throttle heat output of the lower heater element array 108 using both the first tactile temperature measurement 176 and the second tactile temperature measurement 204. In this respect the controller 114 may (a) assign the first lower heater element 168 to a first lower heating zone 206, (b) assign the at least one second lower heater element 170 to a second lower heating zone 208, (c) throttle heat output of the first lower heater element 168 using the first tactile temperature measurement 176 and a first lower heating zone target 210, and (d) throttle heat output of the at least one second lower heater element 170 using the second lower heating zone target 212. It is contemplated that the controller 114 will throttle power applied to the first lower heater element 168 independently of power applied to the at least one second lower heater element 170 using the first tactile temperature measurement 176 and the second tactile temperature measurement 204. For example, the first lower heating zone target 210 may be equivalent to (or different than) the second lower heating zone target 212. Independent throttling of heat generated may be accomplished, for example, using the lower SCR devices 182. In this respect the lower heater element array 108 may be disconnected from the pyrometer 110 by the controller 114, and the upper heater element array 106 may be further disconnected from the thermocouple 112 by the controller 114.

In certain examples, a plurality of lower heater elements (e.g., five (5) or more lower heater elements) of the lower heater element array 108 may be assigned to the first lower heating zone 206 and throttled using the first tactile temperature measurement 176. In accordance with certain examples, six (6) or more lower heater elements of the lower heater element array 108 with the first lower heater element 168 interposed therebetween may be assigned to the second lower heating zone 208 and throttled using the second tactile temperature measurement 204. As will be appreciated by those of skill in the art in view of the present disclosure, throttling heat generated by the lower heater elements underlying the divider 142 using the static thermocouple 202 while throttling heat generated by the lower heater elements underlying the substrate support 104 using the rotating thermocouple 112 may limit cross talk in changes made to heat output by the upper heater element array 106 and the lower heater element array 108 associated with a gap defined between the substrate support 104 and the divider 142, limiting (or eliminating) thickness variation in the material layer 4 induced during deposition that may be otherwise associated with temperature variation associated with the lag.

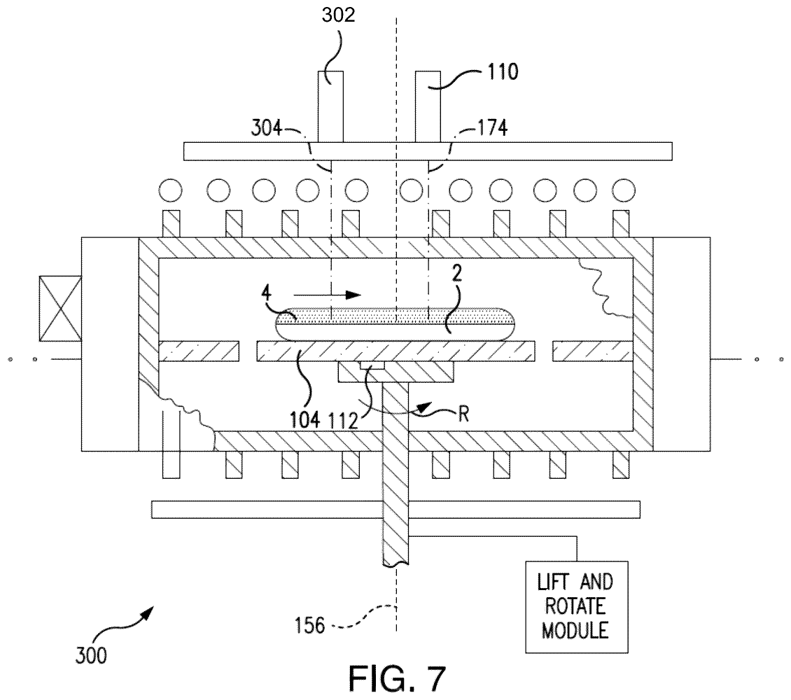

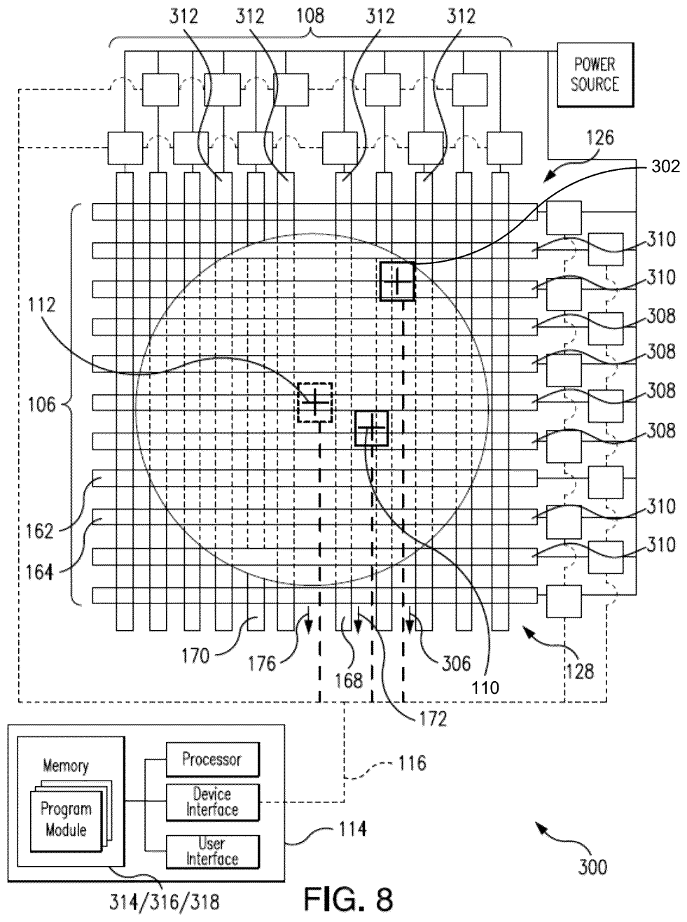

With reference to FIGS. 7 and 8, a chamber arrangement 300 is shown. The chamber arrangement 300 is similar to the chamber arrangement 100 (shown in FIG. 1) and additionally includes a second pyrometer 302. The second pyrometer 302 is arranged along a second optical axis 304 and is arranged radially outward of the first pyrometer 110 relative to the rotation axis 156. It is contemplated that the second optical axis 304 intersect the substrate support 104. More specifically, the second optical axis 304 may intersect the substrate 2 when seated on the substrate support 104, the second pyrometer 302 thereby configured to receive a second optical temperature measurement 306 of the substrate 2 during deposition of the material layer 4 onto the substrate 2. In certain examples, the second optical axis 304 may be laterally offset from the first optical axis 174. In accordance with certain examples, the second optical axis 304 may be longitudinally offset from the first optical axis 174. It is also contemplated that the second optical axis 304 may be both laterally offset and longitudinally offset from the first optical axis 174.

It is contemplated that the second pyrometer 302 be operatively connected to the upper heater element array 106. In this respect it is contemplated that the first upper heater element 162 be operatively associated with the first pyrometer 110, that the second upper heater element 164 be operatively associated with the second pyrometer 302, and the lower heater element array 108 be operatively associated with the thermocouple 112. In this respect the second pyrometer 302 is connected to the controller 114, for example through the wired or wireless link 116, and is configured to provide the second optical temperature measurement 306 to the controller 114. During deposition of the material layer 4 onto the substrate 2, the controller 114 may (a) assign the first upper heater element 162 to a first upper heating zone 308, assign the second upper heater element 164 to a second upper heating zone 310, and assign the first lower heater element 168 and the at least one second lower heater element 170 to a lower heating zone 312; (b) receive the first optical temperature measurement 172 from the first pyrometer 110, receive the second optical temperature measurement 306 from the second pyrometer 302, and receive the tactile temperature measurement 176 from the thermocouple 112; and (c) compare the first optical temperature measurement 172 to a predetermined first upper heating zone target 314, compare the second optical temperature measurement 306 to a predetermined second upper heating zone target 316, and compare the tactile temperature measurement 176 to a predetermined lower heating zone target 318. When any one of the comparisons is outside of a predetermined differential limit, the controller 114 may (d) change power applied to first upper heater element 162, power applied to the second upper heater element 164, and/or power applied to the first lower heater element 168 and the at least one second lower heater element 170 based on the differential.

In certain examples, each of the upper heater elements of the upper heater element array 106 may be distributed into the first upper heating zone 308 and the second upper heating zone 310. For example, a plurality of upper heater elements (e.g., five (5) or more upper heater elements) of the upper heater element array 106 may be assigned to the first upper heating zone 308 and throttled using the first optical temperature measurement 172, and five (5) or more upper heater elements including the second upper heater element 164 may be assigned to the second upper heating zone 310 and throttled using the second optical temperature measurement 306. In accordance with certain examples, each of the lower heater elements may be assigned to the lower heating zone 312 and throttled using the tactile temperature measurement 176 provided by the thermocouple 112. In this respect each of eleven (11) or twelve (12) lower heater elements included in the lower heater element array 108 may be assigned to the lower heating zone 312.

As will be appreciated by those of skill in the art in view of the present disclosure, in addition to the aforementioned advantages relating to limiting feedback associated with changes made to heat output from lower heater elements assigned to the lower heater element array 108, assigning the upper heater elements into the first upper heating zone 308 and the second upper heating zone 310 allows for controlling temperature variation between the center and the edge of the substrate 2. For example, a predetermined first upper heating zone target 314 may be assigned to the first upper heating zone 308, a predetermined second upper heating zone target 316 may be assigned to the second upper heating zone 310, and a temperature difference between the center and the edge of the substrate 2 may be limited (or a non-zero differential maintained) during deposition of the material layer 4 onto the upper surface 6 of the substrate 2. Driving a temperature differential across the substrate 2 using the first optical temperature measurement 172 and the second optical temperature measurement 306, in certain examples, may be employed as a countermeasure to an edge roll-up or edge roll-down material layer profile otherwise characteristic of the material layer deposition process employed in the chamber arrangement 300. Edge-to-center temperature control also may be used in reducing (or eliminating) crystal defects (e.g., slip) as described below in conjunction with FIGS. 14A and 14B.

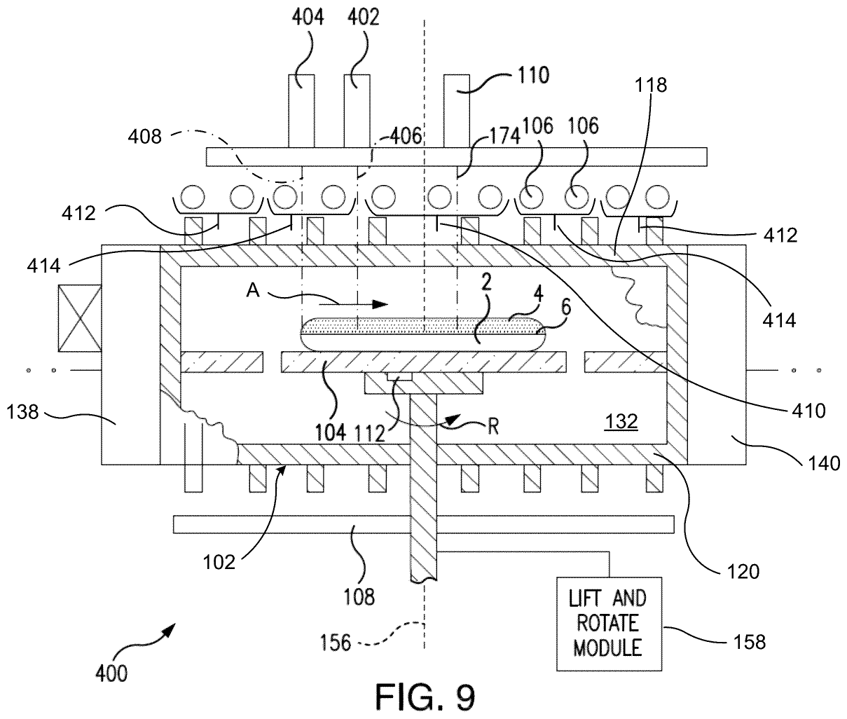

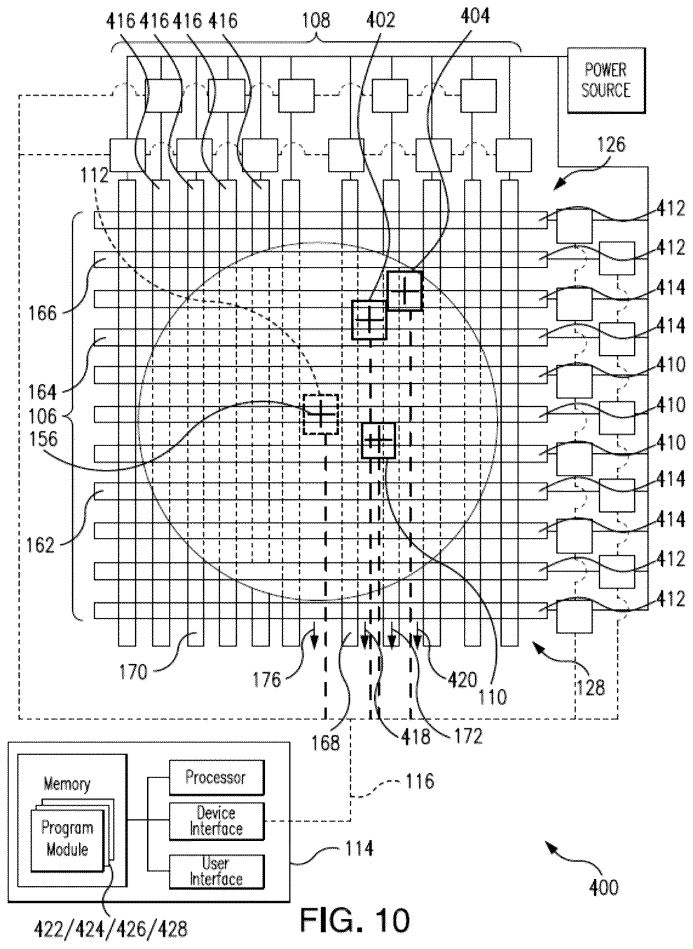

With reference to FIGS. 9 and 10, a chamber arrangement 400 is shown. The chamber arrangement 400 is similar to the chamber arrangement 100 (shown in FIG. 1) and additionally includes a second pyrometer 402 and a third pyrometer 404. The second pyrometer 402 is supported above the upper heater element array 106 and along a second optical axis 406. The second optical axis 406 is radially outward of the first optical axis 174, overlays the substrate support 104, and intersects the substrate 2 when the substrate 2 is seated on the substrate support 104. The second optical axis 406 may be parallel to the first optical axis 174 and may further extend between the first upper heater element 162 and the at least one third upper heater element 166. The second optical axis 406 may intersect the substrate 2 at a location halfway between the substrate 2 center and the substrate 2 edge. The third pyrometer 404 is also supported above the upper heater element array 106, is arranged along a third optical axis 408, and may be parallel to the second optical axis 406. The second optical axis 406 is radially intermediate the first optical axis 174 and the third optical axis 408, the third optical axis 408 also overlaying the substrate support 104 and intersecting the substrate 2 when the substrate 2 is seated on the substrate support 104. In certain examples, the second optical axis 406 may be circumferentially offset from the first optical axis 174 about the rotation axis 156. In accordance with certain examples, the third optical axis 408 may be circumferentially offset from the second optical axis 406 about the rotation axis 156. It is also contemplated that, in accordance with certain examples, the third optical axis 408 may be circumferentially offset from both the first optical axis 174 and the second optical axis 406.

It is contemplated that the second pyrometer 402 and the third pyrometer 404 be operatively connected to the upper heater element array 106. In this respect the first pyrometer 110 may be operatively connected to the first upper heater element 162 to throttle power applied to the first upper heater element 162 to throttle heat generated by the first upper heater element 162 and communicated into the upper chamber 148 (shown in FIG. 3) of the chamber body 102 (shown in FIG. 3). The second pyrometer 402 may be operatively connected to the second upper heater element 164 to throttle power applied to the second upper heater element 164 to throttle heat generated by the second upper heater element 164 and communicated into the upper chamber 148 of the chamber body 102 by the second upper heater element 164. The third pyrometer 404 may be operatively connected to the at least one third upper heater element 166 to throttle heat generated by the at least one third upper heater element 166 and communicated into the upper chamber 148 of the chamber body 102 by the at least one third upper heater element 166. The thermocouple 112 may be operatively connected to the lower heater element array 108 to throttle heat communicated into the lower chamber 150 of the chamber body 102 to throttle heating of the substrate support 104 independent of heating of the substrate 2 by the upper heater element array 106. Operative connection may be through the controller 114. In this respect the first pyrometer 110 and the thermocouple 112 are connected to the controller 114 by the wired or wireless link 116. In further respect, the second pyrometer 402 and the third pyrometer 404 may also be connected to the controller 114 by the wired or wireless link 116. While FIGS. 9 and 10 show: (i) the upper heater element array 106 having its individual lamps arranged perpendicular to the gas flow direction (in the direction shown by arrow A in FIG. 9 from the injection flange 138 to the exhaust flange 140) and (ii) the lower heater element array 108 having its individual lamps arranged parallel to that gas flow direction A, other arrangements are possible. For example, in some examples of this technology: (i) the upper heater element array 106 may have its individual lamps arranged generally parallel to the gas flow direction (in the direction shown by arrow A in FIG. 9) and (ii) the lower heater element array 108 may have its individual lamps arranged perpendicular to that gas flow direction A.

The controller 114 may be configured to (a) assign the first upper heater element 162 to a first upper heating zone 410, assign the at least one third upper heater element 166 to a second upper heating zone 412, assign the second upper heater element 164 to a third upper heater heating zone 414, and assign the first lower heater element 168 and the at least one second lower heater element 170 to a lower heating zone 416. The controller 114 may also be configured to (b) receive the first optical temperature measurement 172 from the first pyrometer 110, receive a second optical temperature measurement 418 from the second pyrometer 402, receive a third optical temperature measurement 420 from the third pyrometer 404, and receive the tactile temperature measurement 176 from the thermocouple 112. It is contemplated that the controller 114 may be further configured to (c) compare the first optical temperature measurement 172 to a predetermined first upper heating zone target 422, compare the second optical temperature measurement 418 to a predetermined second upper heating zone target 424, compare the third optical temperature measurement 420 with a predetermined third upper heating zone target 426, and compare the tactile temperature measurement 176 to a predetermined lower heating zone target 428 to control heating of the substrate 2. When any one of the comparisons indicates that temperature is outside of a predetermined differential limit, the controller 114 may (d) change power applied to first upper heater element 162, change power applied to the at least one third upper heater element 166, change power applied to the second upper heater element 164, and/or change power applied to the first lower heater element 168 and the at least one second lower heater element 170 based on the differential.

In certain examples, each of the upper heater elements of the upper heater element array 106 may be distributed into one of the first upper heating zone 410, a second upper heating zone 412, and a third upper heating zone 414. For example, three (3) centrally positioned upper heater elements of the upper heater element array 106 may be assigned to the first upper heating zone 410, four (4) of the upper heater elements paired on longitudinally opposite sides of the upper heater elements assigned to the first upper heating zone 410 may be assigned to the second upper heating zone 412, and four (4) of the upper heater elements paired and distributed between the upper heater elements of first upper heating zone 410 and those assigned to the second upper heating zone 412 may be assigned to the third upper heating zone 414. As will be appreciated by those of skill in the art in view of the present disclosure, in addition to the aforementioned advantages relating to limiting feedback associated with changes made to heat output from lower heater elements assigned to the lower heater element array 108, assigning the upper heater elements into the first upper heating zone 410, the second upper heating zone 412, and the third upper heating zone 414 enables control of temperature gradient radially across the upper surface 6 of the substrate 2. Control of temperature gradient in turn enables tuning heat flux radially within the substrate 2, for example, to limit likelihood of crystallographic slip defect development in the material layer 4 due to temperature gradient within the substrate 2. These and other features are described in more detail below in conjunction with FIGS. 14A and 14B.

With reference to FIGS. 11-13, a material layer deposition method 500 is shown. As shown in FIG. 11, the material layer deposition method 500 includes supporting a substrate on a substrate support, e.g., the substrate 2 (shown in FIG. 1) on the substrate support 104 (shown in FIG. 3), as shown in box 510. A material layer precursor, e.g., the precursor 16 (shown in FIG. 1), is flowed across the substrate and a material layer, e.g., the material layer 4 (shown in FIG. 1), is deposited onto the substrate using the material layer precursor, as shown with box 520 and box 530. Heat communicated to the substrate during deposition of the material layer onto the substrate with an upper heater element array, e.g., the upper heater element array 106 (shown in FIG. 4), is throttled using an optical temperature measurement acquired by a pyrometer during deposition of the material layer onto the substrate, e.g., using the optical temperature measurement 172 (shown in FIG. 4) acquired using the pyrometer 110 (shown in FIG. 3), as shown with box 540. It is also contemplated that heat communicated to the substrate during deposition of the material layer with a lower heater element array, e.g., the lower heater element array 108 (shown in FIG. 3), be independently throttled using a tactile measurement provided by a thermocouple, e.g., the tactile temperature measurement 176 (shown in FIG. 4) provided by the thermocouple 112 (shown in FIG. 3), as shown with box 550. In this respect it is contemplated that the tactile temperature measurement acquired by the thermocouple 112 not be employed to throttle electrical power applied to upper heater elements of the upper heater element array. In further respect, the optical temperature measurement acquired by the pyrometer may not be employed to throttle electrical power applied to lower heater elements of the lower heater element array.

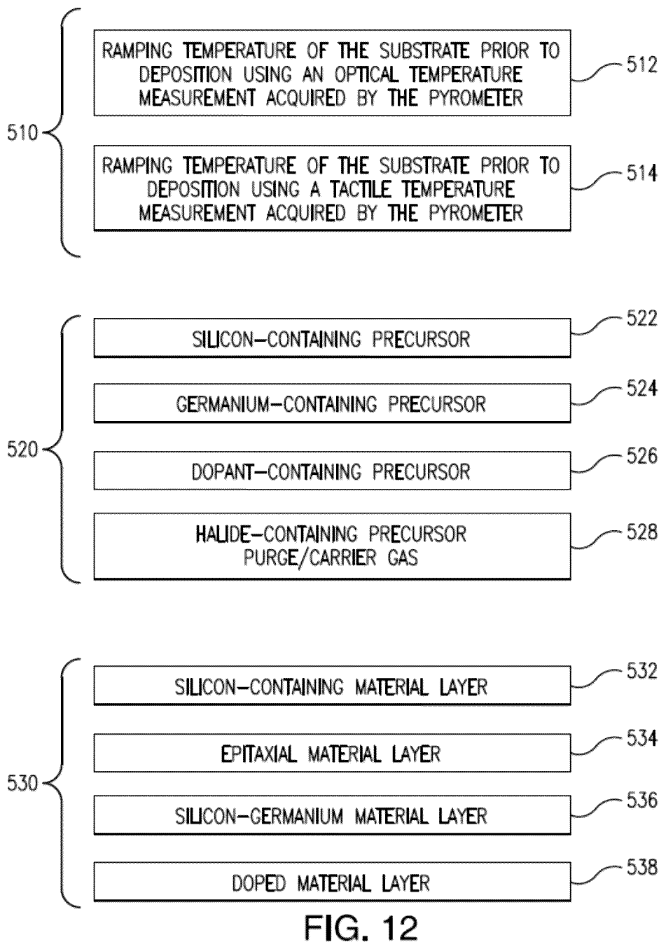

As shown in FIG. 12, seating 510 the substrate may include ramping temperature of the substrate to a predetermined material layer deposition temperature while throttling heat generated by the upper heater element array using optical temperature measurements provided by the pyrometer independent of tactile temperature measurements provided by the thermocouple, as shown with box 512. Seating 510 the substrate on the substrate support may also include ramping temperature of the substrate to the predetermined material layer deposition temperature while throttling heat generated by the lower heater element array using a tactile temperature measurement provided by the thermocouple independent of an optical temperature measurement provided by the pyrometer, as shown with box 514.

Flowing 520 the material layer precursor across the substrate may include flowing a silicon-containing precursor, e.g., the silicon-containing precursor 32 (shown in FIG. 2), across the substrate, as shown with box 522. Flowing 520 the material layer precursor across the substrate may include flowing a germanium-containing precursor, e.g., the germanium-containing precursor 34 (shown in FIG. 2), across the substrate, as shown with box 524. Flowing 520 the material layer precursor across the substrate may include flowing a dopant-containing precursor, e.g., the dopant-containing precursor 36 (shown in FIG. 2), across the substrate, as shown with box 526. Flowing 520 the material layer precursor across the substrate may include flowing a halide-containing material, e.g., the halide-containing material 40 (shown in FIG. 2), across the substrate, as shown with box 528. One of more of the aforementioned precursors and/or the halide-containing material may be carried by a purge/carrier gas, e.g., the purge/carrier gas 38 (shown in FIG. 2), as shown with box 528.

Depositing 530 the material layer onto the substrate may include depositing a silicon-containing material layer onto the substrate, as shown with box 532. Depositing the material layer onto the substrate may include depositing an epitaxial material layer onto the substrate, as shown with box 534. Depositing the material layer onto the substrate may include depositing a silicon-germanium material layer on the substrate, as shown with box 536. The material layer may be doped with phosphorus (P), boron (B), and/or arsenic (As), as shown with box 538.

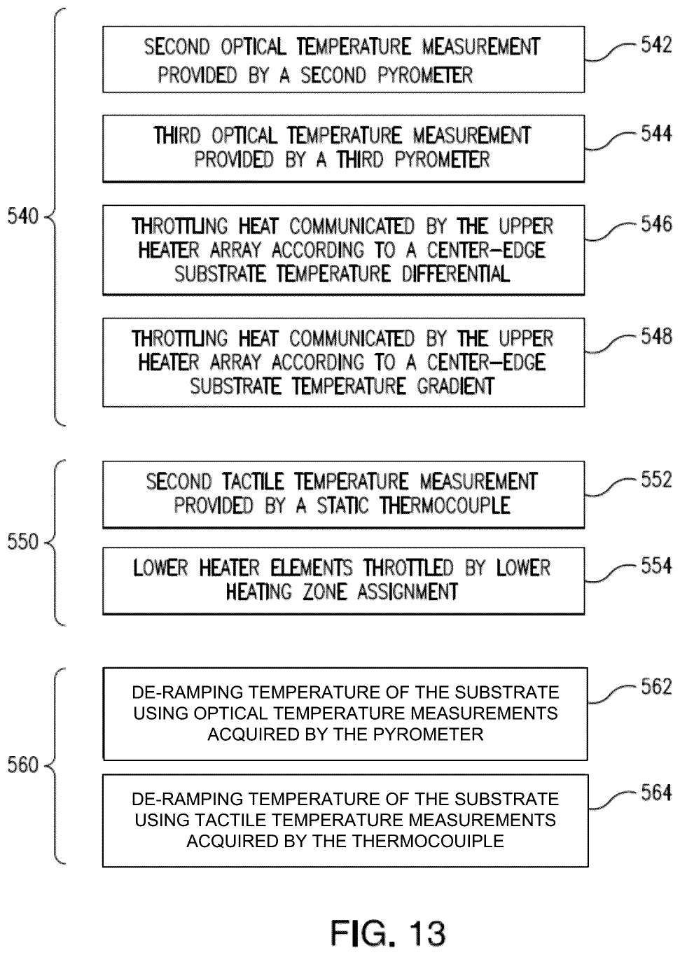

As shown in FIG. 13, heating 540 the substrate with the upper heater element array may include throttling heat generated by the upper heater element array using a second optical temperature measurement acquired by a second pyrometer, e.g., the second optical temperature measurement 306 (shown in FIG. 8) using the second pyrometer 302 (shown in FIG. 7), as shown with box 542. Upper heater elements of the upper heater element array may be assigned into a first upper heating zone operably associated with only the first pyrometer and a second upper heating zone operably associated with only the second pyrometer, e.g., the first upper heating zone 308 (shown in FIG. 8) and the second upper heating zone 310 (shown in FIG. 8), as also shown with box 542. Heating 540 the substrate with the upper heater element array may include throttling heat generated by the upper heater element array using a third optical temperature measurement acquired by a third pyrometer, e.g., the third optical temperature measurement 420 (shown in FIG. 10) using the third pyrometer 402 (shown in FIG. 9), as shown with box 544. Upper heater elements of the upper heater element array may be assigned into heating zones each operatively associated with only one of the pyrometers, e.g., the upper heating zones 410-414 (shown in FIG. 10), as also shown with box 544. As shown with box 546 and box 548, substrate temperature may be throttled according to a temperature differential and/or a temperature gradient across an upper surface of the substrate determined using the first optical temperature measurement and the second optical temperature measurement. For example, a center-edge differential of substrate temperature may be determined using the first optical temperature measurement and the second optical temperature measurement and heat output of the upper heater element array throttled according to the first optical temperature measurement and the second optical temperature measurement as function of radial distance between the rotation axis and edge of the substrate. Alternatively (or additionally) a center-edge gradient of substrate temperature may be determined using the first optical temperature measurement, the second optical temperature measurement, and the third optical temperature measurement by fitting a second order or higher function to the optical temperature measurements. Heat output of the upper heater element array may be throttled according to the greatest slope of lines tangent to the curve as a function of radial distance between the rotation axis and edge of the substrate.

Heating 550 the substrate with the lower heater element array may include throttling heat generated by the lower heater element array using a second tactile temperature measurement acquired by a static thermocouple, e.g., the second tactile temperature measurement 204 (shown in FIG. 6) acquired by the static thermocouple 202 (shown in FIG. 5), as shown with box 552. Heater element of the lower heater element array may be assigned into a first lower heater element zone and a second lower heater element zone, e.g., the first lower heating zone 206 (shown in FIG. 6) and the second lower heating zone 208 (shown in FIG. 6), as shown with box 554. Heat generated by heater elements assigned to the first lower heater element zone may be throttled using only a first tactile temperature measurement acquired by a rotating thermocouple, e.g., the first tactile temperature measurement 176 (shown in FIG. 6) acquired by the rotating thermocouple 112 (shown in FIG. 5), as shown with box 554. Heat generated by lower heater elements assigned to the second lower heater element zone may be throttled using only a second tactile temperature measurement acquired by the static thermocouple, e.g., the first tactile temperature measurement 176 (shown in FIG. 6), as also shown with box 552.

As shown with box 560, the method may include unseating the substrate from the substrate support. Unseating the substrate may include de-ramping temperature of the substrate from the predetermined material layer deposition temperature to an unloading temperature while throttling the upper heater element array using optical temperature measurements provided by the pyrometer independent of tactile temperature measurements provided by the thermocouple, as shown with box 562. Unseating the substrate may also include de-ramping temperature of the substrate from the predetermined material layer deposition temperature to an unloading temperature while throttling the lower heater element array using tactile temperature measurements provided by the thermocouple independent of optical temperature measurements provided by the pyrometer, as shown with box 564.

Additional aspects of this technology relate to use of substrate temperature control during substrate processing, e.g., to control properties and/or improve quality of the processed substrate 2. As some more specific examples, processes in accordance with at least some examples of this technology may use substrate temperature control during substrate processing (e.g., selectively activating and/or controlling power to one or more individual heater elements in the various different heating zones at different times) to control one or more of: (i) the edge substrate temperature (T_{Edge}), (ii) the center substrate temperature (T_{Center}), (iii) the intermediate substrate temperature (T_{Intermediate}), (iv) the edge offset temperature (Edge Offset=T_{Edge}−T_{Center}), (v) the substrate edge and intermediate temperature differential (ΔT_{EI}=|T_{Edge}−T_{Intermediate}|), and/or (vi) the substrate center and intermediate temperature differential (ΔT_{CI}=|T_{Center}−T_{Intermediate}|) during substrate processing. Such substrate temperature control may be used, for example, to control the quality and/or certain properties of the processed substrate, e.g., to reduce or eliminate crystallographic slip, to reduce or eliminate auto-doping, etc.

The processes described below may be used with and/or performed in the chamber arrangements described above (e.g., chamber arrangements 300 and 400 described in conjunction with FIGS. 7-10), as well as with chamber arrangements of the types described in (a) U.S. Patent Appln. Publn. No. US 2022/0298672 A1 filed Mar. 17, 2022; (b) U.S. Patent Appln. Publn. No. US 2022/0301905 A1 filed Mar. 17, 2022; (c) U.S. Provisional Patent Appln. No. 63/162,878 filed Mar. 18, 2021; (d) U.S. Provisional Patent Appln. No. 63/270,653 filed Oct. 22, 2021; (e) U.S. Provisional Patent Appln. No. 63/270,673 filed Oct. 22, 2021; and (f) U.S. Provisional Patent Appln. No. 63/374,181 filed Aug. 31, 2022. Each of U.S. Patent Appln. Publn. No. US 2022/0298672 A1, U.S. Patent Appln. Publn. No. US 2022/0301905 A1, U.S. Provisional Patent Appln. No. 63/162,878, U.S. Provisional Patent Appln. No. 63/270,653, U.S. Provisional Patent Appln. No. 63/270,673, and U.S. Provisional Patent Appln. No. 63/374,181 is entirely incorporated herein by reference. The following discussion will refer back to the systems shown in FIGS. 9 and 10.

The following discussion uses the terms “fast temperature ramping rate” and “slow temperature ramping rate” relating to features of heating a substrate 2 from a first temperature to a second temperature. These temperature ramping rates may be measured and expressed in terms of temperature change from the first temperature to the second temperature over time in units of “° C./second” (i.e., total temperature change (in ° C.)/total time (in seconds)). The terms “fast temperature ramping rate” and “slow temperature ramping rate” within a specific substrate processing method are fast rates and slow rates relative to one another (i.e., the “fast temperature ramping rate” used in a process will be faster than the “slow temperature ramping rate” used in the same process, and the “slow temperature ramping rate” used in a process will be slower than the “fast temperature ramping rate” used in the same process). In at least some examples of this technology, the “slow temperature ramping rate” R_{S} (e.g., in ° C./sec) in a substrate processing method will be no more than 75% of the “fast temperature ramping rate” R_{F} (e.g., in ° C./sec) used in that same substrate processing method (i.e., R_{S}≤0.75×R_{F}). Thus, in a substrate processing method using a “fast temperature ramping rate” of 10° C./sec, the corresponding “slow temperature ramping rate” used in that same processing method will be 7.5° C./sec or less. Additionally or alternatively, in at least some examples of this technology, the “slow temperature ramping rate” in a substrate processing method may be no more than 65% (or even no more than 60%, no more than 50%, no more than 40%, no more than 30%, or no more than 20%) of the “fast temperature ramping rate” used in that same substrate processing method. Additionally or alternatively, in at least some examples of this technology, the “fast temperature ramping rate” R_{F} (e.g., in ° C./sec) in a substrate processing method will be at least 1.3 times the “slow temperature ramping rate” R_{S} (e.g., in ° C./sec) used in that same substrate processing method (i.e., R_{F}≤1.3×R_{S}). Thus, in a substrate processing method using a “slow temperature ramping rate” of 5° C./sec, the corresponding “fast temperature ramping rate” used in that same processing method will be at least 6.5° C./sec. Additionally or alternatively, in at least some examples of this technology, the “fast temperature ramping rate” in a substrate processing method may be at least 1.4 times (or even at least 1.5 times, at least 1.75 times, at least 2 times, at least 2.5 times, at least 3 times, or at least 4 times) the “slow temperature ramping rate” used in that same substrate processing method.

Additionally or alternatively, as some absolute numbers, in at least some examples of this technology, the “fast temperature ramping rate” may be at least 6° C./sec, at least 7° C./sec, at least 8° C./sec, at least 9° C./sec, or even at least 10° C./sec. Additionally or alternatively, as some absolute numbers, in at least some examples of this technology, the “slow temperature ramping rate” may be less than 7.5° C., less than 6° C./sec, less than 5° C./sec, less than 4° C./sec, less than 3° C./sec, or even less than 2° C./sec. For process steps in which the temperature ramping rate changes over the course of time when moving from the first temperature (e.g., TA) to the second temperature (TB), the ramping rate R may be determined as total temperature change in that step (in ° C.)/total time in that step (in seconds) during the temperature ramping step, i.e., R=(TB−TA)/(tB−tA), where R=the ramping rate; TA and tA represent temperature and time, respectively, at the beginning of the ramping step, and TB and tB represent temperature and time, respectively, at the end of the ramping step.

The term “free fall cooling rate” as used herein means natural cooling or uncontrolled cooling within the environment in which the substrate 2 is located (e.g., within a chamber arrangement 400 after layer deposition is complete and before the substrate 2 is removed from the chamber arrangement 400 and moved to another location). “Free fall cooling” may take place in various ways. For example, the controller 114 could power off all heater elements (e.g., in upper heater element array 106 and lower heater element array 108). As another example, the controller 114 could change the temperature “set point” for substrate 2 and/or the chamber arrangement 400 to a level well below the temperature at which the next step will take place (e.g., the controller 114 could set the desired or target substrate temperature and/or chamber arrangement 400 temperature to 500° C. while the substrate processing method will open and remove the substrate 2 from the chamber arrangement 400 when the temperature reaches about 650° C.).

Additional aspects and features of processes in accordance with at least some examples of this technology will be described below. Atmospheric epitaxial silicon layer deposition with trichlorosilane (TCS) and other layer forming processes on substrates take place at high temperatures (e.g., 1050° C. to 1200° C.). In such processes, the substrate processing chamber must be heated (with the substrate temperature ramping upward over time, e.g., from 650° C. to the processing temperature at approx. 1200° C.) and cooled (with the substrate temperature ramping downward over time, e.g., from 1200° C. to 650° C.). If the temperature ramps to quickly, specific regions of a substrate 2 may heat or cool faster than other places, which causes temperature gradients and/or non-uniform temperature distribution inside the substrate 2. Due to thermal expansion, such temperature gradients/non-uniformities generate thermal stresses within the substrate 2. When the thermal stress is sufficiently large, plastic deformation of the substrate 2 may occur, forming slip or crystal line defects (e.g., crystallographic slip).

This potential risk for creating slip defects has caused some manufacturers to use greatly restricted (i.e., slow) temperature ramping rates, e.g., in epitaxial silicon deposition processes. But because large temperature changes typically are required for at least some deposition processes (e.g., between 650° C. and 1200° C.), the use of slow temperature ramping rates make temperature ramping one of the most time consuming steps in some substrate processing methods. Thus, manufacturers are faced with a choice between competing interests. Faster temperature ramping rates will result in more slip defects (and thus less acceptable product) but shorter overall processing times. Slower temperature ramping rates will result in less slip defects but longer overall processing times. Typical substrate processing methods have simply made efforts to strike a balance between these competing interests and optimize the tradeoff between temperature ramping rate and formation of slip defects. Thus, processing techniques that allow faster temperature ramping, high throughput, and reduced defect production would be welcome advances in the art.

In accordance with the following aspects of this technology, temperature ramping takes place in multiple steps. Further, during temperature ramping and substrate processing, the pyrometer temperatures at least at the substrate center and substrate edge are measured (using pyrometers (e.g., 110, 404) of the types described above). By selectively controlling individual heater elements in the zones of (e.g., upper heating zones 410, 412) the upper heater array, heating at least in the center region and edge region of the substrate 2 is controlled to set and maintain a desired temperature gradient across the substrate 2 during temperature ramping and de-ramping (heating and cooling) and substrate 2 processing (layer growth). Aspects of this technology use the optically measured edge substrate temperature (T_{Edge}) and the optically measured center substrate temperature (T_{Center}) to determine an edge offset temperature parameter (Edge Offset=T_{Edge}−T_{Center}), and this edge offset temperature parameter is controlled to maintain a desired temperature gradient across the substrate 2.

FIG. 14A generally illustrates substrate processing methods 1400 in accordance with some examples of this technology (reference numbers in FIGS. 14A and 15 beginning with the label “S” (e.g., “S14XX” and “S15XX”) also may be referred to herein as “steps” of the processes described in conjunction with these figures). This substrate processing method 1400 may take place, e.g., using a chamber arrangement 400 of the types shown in FIGS. 9 and 10. As a first step S1402, a substrate 2 is placed on substrate support 104 (e.g., a susceptor) located in chamber arrangement 400. This chamber arrangement 400 may include: (i) a chamber body 102 having an upper wall 118 and a lower wall 120, (ii) the substrate support 104 arranged within an interior 132 of the chamber body 102 and supported for rotation about a rotation axis 156, (iii) an upper heater element array 106 supported above the upper wall 118 of the chamber body 102, wherein heater elements of the upper heater element array 106 include a first upper heating zone 410 (a center heating zone) and a second upper heating zone 412 (an edge heating zone), (iv) a pyrometer 110 supported above the upper heater element array 106, optically coupled to the interior 132 of the chamber body 102, and configured to optically measure a center substrate temperature (T_{Center}), (v) another pyrometer 404 supported above the upper heater element array 106, optically coupled to the interior 132 of the chamber body 102, and configured to optically measure an edge substrate temperature (T_{Edge}), and (vi) a controller 114 (see FIG. 10) to control power applied to the heater elements of the upper heater element array 106. In at least some examples of this technology: (i) the chamber arrangement 400 further may include another pyrometer 402 supported above the upper heater element array 106, optically coupled to the interior 132 of the chamber body 102, and configured to optically measure an intermediate substrate temperature (T_{Intermediate}), e.g., a substrate temperature at a location that is between (e.g., at a midpoint (R/2) between) the substrate 2's center and edge, and (ii) the heater elements of the upper heater element array 106 further may include a third upper heating zone 414 (an intermediate heating zone) located between the first upper heating zone 410 and the second upper heating zone 412. Once the substrate 2 is seated on the substrate support 104, the chamber arrangement 400 may be closed (e.g., sealed) to allow a deposition process to begin.

The substrate processing method 1400 of this example further includes a first “fast” temperature ramping process S1404 in which substrate temperature is increased at a fast temperature ramping rate. This first fast temperature ramping process S1404 corresponds to region A shown in FIG. 14B. When initially introduced into the chamber arrangement 400, the substrate 2 may be at a first (or initial) temperature T1. During this first fast temperature ramping process S1404, the controller 114 may selectively control power applied to one or more of the heater elements of the upper heater element array 106 to ramp up the substrate temperature relatively quickly (e.g., at 10° C./s) to a second temperature T2. As one specific example, this first fast temperature ramping process S1404 may ramp substrate temperature up from its original starting point T1 (e.g., 650° C.) to T2 (e.g., 900° C. to 1000° C.) at an average ramping rate R1 of 10° C./s.

During this first fast temperature ramping process S1404 (and/or any one or more of the other process steps shown in substrate processing method 1400), the center substrate temperature (T_{Center}) of the substrate 2 may be optically measured using pyrometer 110, and the edge substrate temperature (T_{Edge}) of the substrate 2 may be optically measured using pyrometer 404. Further, during this first fast temperature ramping process S1404 step (and/or any one or more of the other process steps shown in substrate processing method 1400), the edge offset temperature EO (i.e., (T_{Edge})−(T_{Center})) may be determined. In at least some examples of this technology, during this first fast temperature ramping process S1404 (and/or any one or more of the other process steps shown in substrate processing method 1400), the intermediate substrate temperature (T_{Intermediate}) of the substrate 2 may be optically measured using pyrometer 402. Additionally, in at least some examples of this technology, during this first fast temperature ramping process S1404 (and/or any one or more of the other process steps shown in substrate processing method 1400), the substrate edge and intermediate temperature differential (ΔT_{EI}=|T_{Edge}−T_{Intermediate}|) and/or the substrate center and intermediate temperature differential (ΔT_{CI}=|T_{Center}−T_{Intermediate}|) may be determined. At least some of these temperatures (e.g., T_{Edge}, T_{Center}, and/or T_{Intermediate}) and/or these temperature differentials (e.g., EO, ΔT_{EI}, and/or ΔT_{CI}) may be provided as inputs to an algorithm used by controller 114 to determine which individual heater elements of the upper heater element array 106 within the first upper heating zone 410, the second upper heating zone 412, and/or the third upper heating zone 414 should be activated, the power to be applied to the individual heater elements, and/or the amount of time to apply the power to provide the desired substrate temperature ramping rate, the desired substrate temperatures in the regions, and/or the desired temperature gradient across the substrate 2.

After T2 is reached during the first fast temperature ramping process S1404, a second fast temperature ramping process S1406 begins in which substrate temperature is increased from the second temperature T2 to a third temperature T3 at a fast temperature ramping rate. This second fast temperature ramping process S1406 corresponds to region B in FIG. 14B. During this second fast temperature ramping process S1406, the controller 114 may selectively control power applied to one or more of the heater elements of the upper heater element array 106 to ramp up the substrate temperature relatively quickly (e.g., at 10° C./s) to the third temperature T3. As one specific example, this second fast temperature ramping process S1406 may ramp substrate temperature up from T2 (e.g., 900° C. to 1000° C.) to T3 (e.g., 1100° C.) at an average rate R2 of 10° C./s.

The fast temperature ramping rate during the second fast temperature ramping process S1406 may be the same as or different from the fast temperature ramping rate used during the first fast temperature ramping process S1404. As some more specific examples, the temperature ramping rate R1 during the first fast temperature ramping process S1404 and the temperature ramping rate R2 during the second temperature ramping process S1406 may be within 20% of one another (e.g., R1=R2±20% and/or R2=R1±20%). But, because of the higher temperatures present during the second fast temperature ramping process S1406, crystal defects, such as crystallographic slip, is more likely to occur during the second fast temperature ramping process S1406 than during the first fast temperature ramping process S1404 (e.g., if high thermal stress is present). Thus, during the second fast temperature ramping process S1406, the controller 114 controls power applied to one or more heater elements in at least one of the first upper heating zone 410 and/or the second upper heating zone 412 to place and/or hold the edge offset temperature EO within a first predetermined range (e.g., +2° C.) of a desired set point (e.g., the EO set point may be a value between −8° C. and +2° C.). Also, in at least some examples of this technology, during this second fast temperature ramping process S1406, the controller 114 may control power applied to one or more heater elements in the first upper heating zone 410, one or more heater elements in the second upper heating zone 412, and/or one or more heater elements in the third upper heating zone 414 (if present) to place and/or hold the substrate edge and intermediate temperature differential ΔT_{EI} and/or the substrate center and intermediate temperature differential ΔT_{CI} within desired ranges of predetermined ΔT_{EI} and/or ΔT_{CI} set points.

Various controller 114 process parameters may differ between the first fast temperature ramping process S1404 and the second fast temperature ramping process S1406. For example, the edge offset temperature EO may be more tightly controlled in the second fast temperature ramping process S1406 than in the first fast temperature ramping process S1404 (e.g., the EO may be maintained within a tighter range of a set point during S1406 than during S1404, or EO may remain uncontrolled during S1404). As other potential differences, the substrate edge and intermediate temperature differential ΔT_{EI} and/or the substrate center and intermediate temperature differential ΔT_{CI} may be more tightly controlled in the second fast temperature ramping process S1406 than in the first fast temperature ramping process S1404 (e.g., ΔT_{EI} and/or ΔT_{CI} may be maintained within a tighter range of their set points during S1406 than during S1404, and/or ΔT_{EI} and/or ΔT_{CI} may remain uncontrolled during S1404).

Returning to FIGS. 14A and 14B, a third temperature ramping process S1408 is shown after the second fast temperature ramping process S1406. This third temperature ramping process S1408 uses a slow temperature ramping rate to increase the substrate temperature from the third temperature T3 to a fourth temperature T4 (which may correspond to a set point temperature or final desired substrate temperature to be used during layer deposition, e.g., epitaxial silicon layer deposition). This third temperature ramping process S1408 corresponds to region C in FIG. 14B. During the third temperature ramping process S1408, the controller 114 controls power applied to one or more heater elements in the first upper heating zone 410 and one or more heater elements in the second upper heating zone 412 to place and/or hold the edge offset temperature EO within a second predetermined range, which may be the same as or different from the first predetermined range discussed above used during the second fast temperature ramping process S1406. The set point for the desired edge offset temperature EO may be the same as or different in this third temperature ramping process S1408 than in the second fast temperature ramping process S1406. Also, in at least some examples of this technology, during this third temperature ramping process S1408, the controller 114 controls power applied to one or more heater elements in the first upper heating zone 410, one or more heater elements in the second upper heating zone 412, and/or one or more heater elements in the third upper heating zone 414 (if present) to place and/or hold the substrate edge and intermediate temperature differential ΔT_{EI} and/or the substrate center and intermediate temperature differential ΔT_{CI} within desired ranges of predetermined ΔT_{EI} and/or ΔT_{CI} set points for this step.

As noted, the third temperature ramping process S1408 uses a slow temperature ramping rate R3 as compared to the temperature ramping rate R1 during the first fast temperature ramping process S1404 and the temperature ramping rate R2 during the second fast temperature ramping process S1406. As some more specific examples, R3 may be 40% less than R1 and/or 40% less than R2 (e.g., in degrees C./sec), and in some examples 50% less than R1, 50% less than R2, 60% less than R1, 60% less than R2, 70% less than R1, 70% less than R2, 80% less than R1, and/or 80% less than R2. As some more absolute ranges: (i) R1 and/or R2 may be at least 6° C./second, and in some examples, at least 7° C./second, at least 8° C./second, at least 9° C./second, or even at least 10° C./second, and/or (ii) R3 may be less than 6° C./second, and in some examples, less than 5° C./second, less than 4° C./second, less than 3° C./second, or even less than 2° C./second.

Once the substrate temperature reaches its desired set point (e.g., T4), in this example substrate processing method 1400, process gas (e.g., for epitaxial silicon growth, for producing doped layers, etc.) is supplied to the chamber arrangement 400 in Step S1410. Step S1410 corresponds to region D in FIG. 14B. The process gas includes a material layer precursor that flows across the substrate 2 and deposits as a layer onto the substrate 2 to build the crystal structure on the substrate 2, e.g., as described above in conjunction with FIG. 2.

During this process Step S1410, the controller 114 controls power applied to one or more heater elements in the first upper heating zone 410 and/or one or more heater elements in the second upper heating zone 412 to place and/or hold the edge offset temperature EO within a third predetermined range (which may be the same as or different from the first predetermined range and/or the second predetermined range discussed above) of a predetermined set point (which may be the same as or different from set point used in third temperature ramping process S1408). Also, in at least some examples of this technology, during this process Step S1410, the controller 114 may control power applied to one or more heater elements in the first upper heating zone 410, one or more heater elements in the second upper heating zone 412, and/or one or more heater elements in the third upper heating zone 414 (if present) to place and/or hold the substrate edge and intermediate temperature differential ΔT_{EI} and/or the substrate center and intermediate temperature differential ΔT_{CI} within desired ranges of predetermined ΔT_{EI} and/or ΔT_{CI} set points for this Step S1410. In this manner, a desired uniform temperature and/or desired temperature gradient can be maintained on the substrate 2.

Once all desired layers have been deposited on the substrate 2, an initial controlled cooling process S1412 begins (to cool down the substrate 2 so it can be removed from the chamber arrangement 400 and moved to another location (e.g., for further processing)). This initial controlled cooling process S1412 corresponds to region E in FIG. 14B, and it takes the substrate 2 down from the processing temperature (e.g., T5, which may be the same as or different from T4) to an initial “cooled temperature” (e.g., T6). As some more specific examples, the processing temperature T5 may be about 1130° C. to 1200° C. (or higher), and the initial cooled temperature T6 may be about 900° C. This initial controlled cooling process S1412 cools the substrate 2 at a rate R4 slower than would result from a “free fall” cooling technique.

At such high temperatures, crystal defects (e.g., crystallographic slip) can still form (e.g., if sufficient thermal stresses are present). Thus, this initial controlled cooling process S1412 maintains at least the edge offset temperature EO within a predetermined range of a predetermined set point until the substrate 2 reaches T6. During this initial controlled cooling process S1412, the controller 114 controls power applied to one or more heater elements in the first upper heating zone 410 and/or one or more heater elements in the second upper heating zone 412 (i) to place and/or hold the edge offset temperature EO within a controlled temperature differential range (which may be the same as or different from the first predetermined range, the second predetermined range, and/or the third predetermined range discussed above) of a predetermined set point (which may be the same as and/or different from the other EO set points described above) and (ii) to cool the substrate 2 at a cooling rate (e.g., less than 5° C./second) that is slower than a free fall cooling rate under the chamber arrangement 400 conditions present. Also, in at least some examples of this technology, during this initial controlled cooling process S1412, the controller 114 may control power applied to one or more heater elements in the first upper heating zone 410, one or more heater elements in the second upper heating zone 412, and/or one or more heater elements in the third upper heating zone 414 (if present) to place and/or hold the substrate edge and intermediate temperature differential ΔT_{EI} and/or the substrate center and intermediate temperature differential ΔT_{CI} within desired ranges of predetermined ΔT_{EI} and/or ΔT_{CI} set points for this initial controlled cooling process S1412. In this manner, a desired uniform temperature and/or desired temperature gradient can be maintained on the substrate 2.

Further, in this example substrate processing method 1400, after the substrate 2 reaches the first cooled temperature T6 as a result of this initial controlled cooling process S1412, formation of crystal defects (e.g., crystallographic slip) is much more unlikely than at the higher processing temperatures (e.g., T3, T4, T5, etc.). Thus, further cooling of the substrate 2 (from T6 to T7) takes place using a free fall cooling technique in Step S1414. Step S1414 corresponds to region F in FIG. 14B. In at least some examples, during Step S1414, no power is applied to the upper heater element array 106 (and, if present, to the lower heater element array 108), and the substrate 2 is allowed to cool down, e.g., to substrate handling temperature T7. Once cooled (e.g., to 650° C. or lower), the substrate 2 can be removed from the chamber arrangement 400, e.g., for further processing (Step S1416).

Thus, as described above, substrate processing method 1400 in accordance with aspects of this technology described in conjunction with FIGS. 14A and 14B include three distinct substrate temperature increase processes (S1404, S1406, and S1408) and two distinct substrate cooling processes (S1412 and S1414). Further, the edge offset temperature EO is monitored and controlled at least during processes S1406, S1408, S1412 and during the substrate processing steps (e.g., layer growth Step S1410). These features help maintain a uniform temperature and desired temperature gradient across the substrate 2 and reduce (or eliminate) crystal defects in the grown layers.

Appropriate edge offset temperatures EO, ranges of acceptable edge offset temperature differentials, and “recipes” for applying power to the individual heater elements of the upper heater element array 106 may be determined experimentally. Each individual heater element of the upper heater element array 106 may be individually powered (and/or powered as part of a grouping of heater elements) to set and maintain the substrate temperature within desired ranges of predetermined set points for the center, edge, and (in some instances) intermediate locations during substrate heating, processing (e.g., layer deposition), and cooling. The powering “recipe” may include information for controlling each individual heater element, such as: when to apply power to the heater element; what power level to apply to the heater element; when to turn off or reduce power to the heater element; etc. Power may be applied to the individual heater elements under control of the controller 114. Because substrate temperature change response rate at the substrate edge typically is slower than substrate temperature change response rate at the substrate center, typically, to help maintain a uniform temperature distribution across the substrate 2: (i) a positive edge offset temperature EO will be applied (e.g., set and maintained) during temperature ramp up processes (e.g., S1404, S1406, S1408) and (ii) a negative edge offset temperature EO will be applied (e.g., set and maintained) during controlled temperature ramp down steps (e.g., S1412).

In at least some epitaxial silicon layer deposition substrate processing methods 1400 in accordance with examples of this technology, the first fast temperature ramping process S1404 may be used between T1 at 650° C. and T2 at 1000° C., and the ramping rate R1 over this temperature range (an average) may be about 10° C./second. Then, the second fast temperature ramping process S1406 may be used between T2 at 1000° C. and T3 at 1100° C., and the ramping rate R2 over this temperature range (an average) also may be about 10° C./second. As described above, edge offset temperature EO is monitored and controlled at least throughout this second fast temperature ramping process S1406 to reach and stay within a first predetermined range (e.g., −8° C.≤ EO≤2° C. or a more targeted sub-range within that range). Then, a slow third temperature ramping process S1408 is used between T3 (e.g., 1100° C.) and a final “set” point or target processing temperature T4 (e.g., 1130° C. to 1200° C. or higher). The ramping rate R3 over this temperature range (an average) may be 5° C./second or lower (e.g., down to less than 2° C./second). After substrate processing (Step S1410), the first initial controlled cooling process S1412 takes place, e.g., from the end processing temperature T5 (e.g., 1130° C. to 1200° C. or higher) down to a first cooled temperature T6 (at which there may be relatively low risk of crystal defect formation), such as about 900° C. The cooling rate during this initial controlled cooling process S1412 may be at about 5° C./second or less (e.g., 4° C./second or less, 3° C./second or less, or even 2° C./second or less). Step S1414 includes a free fall cooling rate from T6 (e.g., about 900° C.) to the substrate handling temperature T7 (e.g., about 650° C.). Thus, a heating and cooling process in accordance with this technology may follow the following time path resulting in a heat up time of about 51 seconds and a controlled cool down time of 46 seconds:

| Step | Start Temp | End Temp | Ramp Rate | Elapsed Time |
|---|---|---|---|---|
| S1404 | 650° C. | 1000° C. | 10° C./sec | 35 sec |
| S1406* | 1000° C. | 1100° C. | 10° C./sec | 10 sec |
| S1408* | 1100° C. | 1130° C. | 5° C./sec | 6 secs |
| S1412* | 1130° C. | 900° C. | −5° C./sec | 46 secs |

*At least these steps include monitoring edge offset temperature EO and controlling heater elements to get and maintain EO within predetermined ranges of desired set points.

Further, this process was found to substantially avoid or significantly reduce crystal defects, such as crystallographic slip.

In contrast, other epitaxial silicon layer deposition processes not in accordance with this aspect of the present technology include two temperature ramping steps: (i) a first temperature ramp from 650° C. to 900° C. using a fast ramp rate (e.g., 10° C./second) and (ii) a second temperature ramp from 900° C. to 1130° C. at a slow ramp rate (e.g., 5° C./second). Thus, the heating time in this process would be about 71 seconds (25 seconds for the first temperature ramp and 46 seconds for the second temperature ramp). These processes also use free fall cooling, which takes at least 65 seconds and risks crystal defect formation at the higher temperatures. As described above, these processes typically strike a balance between overall processing speed and crystal defect formation.

Thus, processes in accordance with aspects of the present technology (e.g., like substrate processing methods 1400 shown and discussed above in conjunction with FIGS. 14A and 14B) unexpectedly and surprisingly provide faster heat up times, faster overall processing times, and faster substrate throughput rates while producing high quality products with reduced crystal defects (such as crystallographic slip).

As noted above, in at least some examples of this technology, the substrate processing methods 1400 may measure and use the intermediate substrate temperature (e.g., measured using pyrometer 402), e.g., during one or more of the first fast temperature ramping process S1404, the second fast temperature ramping process S1406, the slow third temperature ramping process S1408, the processing step(s) S1410, and/or the initial controlled cooling process S1412. This intermediate substrate temperature (e.g., at a location halfway between the substrate center and substrate edge) may provide additional data points for determining whether a uniform temperature and/or a desired temperature gradient has been achieved and/or maintained across the substrate 2 during the various steps. During any of these steps, the controller 114 may control power applied to one or more heater elements in the third upper heating zone 414 (and/or one or more heater elements in the first upper heating zone 410 and/or the second upper heating zone 412) to place and/or hold the intermediate substrate temperature within a predetermined temperature range from the center substrate temperature and/or within a predetermined range from the edge substrate temperature. In processes in accordance with at least some examples of this technology, the intermediate substrate temperature (and/or the center substrate temperature) may be controlled to be equal to and/or within a predetermined temperature range of the center substrate temperature.

Measuring and controlling the intermediate substrate temperature may provide other advantageous effects. Epitaxial deposition of silicon films is commonly accomplished by seating a substrate 2 on a support 104 (e.g., a susceptor) and heating the substrate 2 to a desired deposition temperature, e.g., as described above. Once the substrate 2 reaches the desired deposition temperature, a silicon-containing precursor is provided within the chamber arrangement 400, and a film is deposited onto the substrate 2 using the silicon-containing precursor. Once the film reaches a desired film thickness, flow of the silicon-containing precursor gas ceases, and the substrate 2 is cooled to a temperature suitable for removal of the substrate 2 from the chamber arrangement 400 (e.g., 650° C.).

During the deposition step in at least some processes, a dopant precursor co-flows with the silicon-containing precursor so that portions of the substrate 2 will reach a desired resistivity profile and magnitude. The dosage of dopant precursor and substrate temperature determine the resistivity magnitude of the epitaxial film.

During epitaxial growth, dopants in substrates 2 can evaporate and/or migrate from the substrates 2 (e.g., from the bottom of doped silicon wafers) and incorporate into the epitaxial films being deposited at the top of the substrate 2. This process is known as “auto-doping.” Auto-doping can be particularly severe when using or producing heavily doped silicon wafers. Auto-doping can cause non-uniform resistivity in the substrates 2 grown in such processes (because the dopant leaves some areas of the substrate 2 thereby depleting dopant concentration there and dopant redeposits at other areas thereby increasing dopant concentration there). Such auto-doping can cause degraded performance and/or unacceptable products. One main factor impacting auto doping is substrate edge temperature, which affect both dopant diffusivity and incorporation rate.

In accordance with at least some examples of this technology, as described above, direct optical substrate temperature measurements are acquired using a center pyrometer 110, an intermediate pyrometer 402 (e.g., at location R/2 of substrate 2 radius R), and an edge pyrometer 404 during one or more of: (i) a temperature ramp up step (e.g., one or more of processes S1404, S1406, and/or S1408), (ii) a layer deposition step (e.g., process Step S1410), and (iii) the temperature ramp down step (e.g., initial controlled cooling process S1412). A gradient of substrate temperature may be determined during one or more of these steps, compared to a predetermined gradient limit, and ratios of radiant energies delivered to the substrate 2 within a center zone, within an intermediate zone, and within an edge zone are controlled to maintain the temperature gradient at the substrate surface to within the predetermined gradient limit.

In scenarios where auto-doping effects are present to an extent that resistivity uniformity and product performance are degraded, control of the edge offset temperature EO may be used: (a) to lower substrate edge temperature in order to lower the migration rate of dopant elements from substrate 2 backside to the epitaxial film in the gas phase and (b) to lower incorporation of gas phase dopant elements into the epitaxial film. While lowering the edge temperature could have the effect of generating slip defects, the measured intermediate substrate temperature (by pyrometer 402) can be used to control the intermediate substrate temperature and mitigate abrupt temperature drops from the substrate 2's mid-radius area to its edge. In other words, using the measured optical temperatures at the substrate edge (from pyrometer 404) and at the substrate intermediate area (from pyrometer 402), the controller 114 can control one or more heater elements in the second upper heating zone 412 and/or in the third upper heating zone 414 to reduce (e.g., minimize) the mid-edge temperature difference (i.e., ΔT_{EI}=|T_{Edge}−T_{Intermediate}|). This process has successfully mitigated the auto-doping effect while still avoiding the slip defects at the substrate edge, e.g., when used in a process like substrate processing method 1400 shown and discussed above in conjunction with FIGS. 14A and 14B.

In the examples of FIGS. 9, 10, 14A, and 14B above, the chamber arrangement 400 is adapted to provide 3-zone substrate temperature control for lamp banks employed during epitaxial growth with multiple linear lamps. As discussed above, the linear lamps may be separated into three groups (i.e., a center group including the first upper heating zone 410, an edge group including the second upper heating zone 412, and an intermediate group including the third upper heating zone 414 in FIG. 10). The lamps of the upper heater element array 106 may be operated using three closed-loop proportional-integral-derivative (PID) controls or other control approaches to get and maintain three substrate temperature (e.g., center, edge, and intermediate substrate temperatures) at desired set points (within predetermined ranges of their set points). Three pyrometers 110, 402, and 404 may be used to optically measure substrate center, intermediate, and edge zone temperatures repeatedly during the various process steps. The temperature readings are provided as feedback to the controller 114 and used to actuate the power of individual heaters within the three upper heating zones 410, 412, 414 to control and maintain substrate temperatures. Inside of each of upper heating zones 410, 412, 414, there are multiple linear lamps, and a power ratio can be assigned to each linear lamp as an open-loop lamp power control, e.g., using an SCR or other controller 114. In this manner, each lamp's power is controlled by SCR or other controller 114 to achieve accurate and repeatable lamp power control. PID controllers and their use are known and are commercially available, e.g., for controlling systems to reach and maintain a temperature set point.

In at least some examples of this technology, during the first fast temperature ramping process S1404 (from temperature T1 to T2 at temperature ramping rate R1, which may be about 10° C./second on average), the substrate 2 remains at a relatively low temperature (e.g., below 1000° C.). During this step, particularly early on, the potential for generating crystal defects is relatively low. Thus, during this first fast temperature ramping process S1404, the controller 114 may not consider and/or control the edge offset temperature EO and/or the acceptable predetermined range for EO may be set relatively high (e.g., +10° C.). Additionally, at this first fast temperature ramping process S1404: (a) the controller 114 may not consider and/or control the intermediate substrate temperature (T_{Intermediate}), the substrate edge and intermediate temperature differential (ΔT_{EI}), and/or the substrate center and intermediate temperature differential (ΔT_{CI}) and/or (b) the acceptable predetermined ranges for one or more of the intermediate substrate temperature (T_{Intermediate}), the substrate edge and intermediate temperature differential (ΔT_{EI}), and/or the substrate center and intermediate temperature differential (ΔT_{CI}) may be set relatively high.

During the second fast temperature ramping process S1406 (from temperature T2 to T3 at temperature ramping rate R2, which may be about 10° C./second on average), the substrate 2 reaches higher temperatures (e.g., above 1000° C.). During this time period, the potential for crystal defects is higher. Thus, during this second fast temperature ramping process S1406, substrate temperatures will be optically measured using pyrometers 110 (substrate center) and 404 (substrate edge), and this information can be used to determine the edge offset temperature EO. Further, the controller 114 will control heater elements within the first upper heating zone 410 and the second upper heating zone 412 using the optical temperatures measured to set and maintain the edge offset temperature EO at a desired level (a desired set point) and within a desired range of that set point (e.g., EO may be set at +2° C. with an acceptable range of +3° C.). Additionally, during this second fast temperature ramping process S1406, the controller 114 may use optical temperature data measured by pyrometers 110, 402, and 404 to control heater elements within the first upper heating zone 410, the second upper heating zone 412, and/or the third upper heating zone 414 to set and maintain one or more of: (i) the intermediate substrate temperature (T_{Intermediate}), (ii) the substrate edge and intermediate temperature differential (ΔT_{EI}), and/or (iii) the substrate center and intermediate temperature differential (ΔT_{CI}) at desired levels and/or within desired ranges. In this manner, relatively uniform temperatures and/or desired temperature gradients can be maintained on the substrate 2 during the second fast temperature ramping process S1406.

During the slow third temperature ramping process S1408 (from temperature T3 to T4 at temperature ramping rate R3, which may be about 6° C./second or less on average), the substrate 2 reaches still higher temperatures (e.g., above 1100° C.). During this time period, the potential for crystal defects is even higher. During this slow third temperature ramping process S1408, the substrate temperatures will continue to be measured optically by pyrometer 110 (substrate center) and pyrometer 404 (substrate edge) and the edge offset temperature EO will continue to be determined. Further, the controller 114 will control heater elements within the first upper heating zone 410 and the second upper heating zone 412 using the optical temperatures measured to set and maintain the edge offset temperature EO at a desired level (a desired set point) and within a desired range of that set point (e.g., EO may be set at +2° C. with an acceptable range of ±1.5° C.). Thus, the acceptable EO range may be tighter (i.e., smaller) during this slow third temperature ramping process S1408 than during the second fast temperature ramping process S1406 (and tighter (i.e., smaller) than during the first fast temperature ramping process S1404, if any were used). Additionally, during this slow third temperature ramping process S1408, the controller 114 may use optical temperature data measured by pyrometers 110, 402, and 404 to control heater elements within the first upper heating zone 410, the second upper heating zone 412, and/or the third upper heating zone 414 to set and maintain one or more of: (i) the intermediate substrate temperature (T_{Intermediate}), (ii) the substrate edge and intermediate temperature differential (ΔT_{EI}), and/or (iii) the substrate center and intermediate temperature differential (ΔT_{CI}) at desired levels and/or within desired ranges. The desired range(s) for T_{Intermediate}, ΔT_{EI}, and/or ΔT_{CI} during this slow third temperature ramping process S1408 may be tighter (i.e., smaller) than the range(s) used for corresponding parameters during the second fast temperature ramping process S1406 (and tighter (i.e., smaller) than the range(s) used for corresponding parameters during the first fast temperature ramping process S1404, if any were used). In this manner, relatively uniform temperatures and/or desired temperature gradients can be maintained on the substrate 2 during the slow third temperature ramping process S1408 and the “set point” temperature and/or differentials can be reached and maintained without excessive temperature over-shoot and/or loss of control of the temperature within the chamber arrangement 400.

During the layer depositing step(s) (while process gas is being supplied to the chamber arrangement 300 in Step S1410), the substrate temperature may remain relatively constant, e.g., at T4, and/or the temperature may change over time (e.g., from T4 to T5). The processing temperature(s) T4 and/or T5 are high (e.g., from 1130° C. to 1200° C. or higher). During this time period, the potential for crystal defects is high. Thus, during processing Step S1410, the controller 114 will use the edge offset temperature EO data (derived from optical substrate temperatures measured by pyrometer 110 (substrate center) and pyrometer 404 (substrate edge)) to control heater elements within the first upper heating zone 410 and the second upper heating zone 412 to set and maintain the edge offset temperature EO at a desired level (a desired set point) and within a desired range of that set point (e.g., EO may be set at +0° C. with an acceptable range of ±1° C.). Additionally, during Step S1410, the controller 114 may use optical temperature measurement data from pyrometers 110, 402, and 404 to control heater elements within the first upper heating zone 410, the second upper heating zone 412, and/or the third upper heating zone 414 to set and maintain one or more of: (i) the intermediate substrate temperature (T_{Intermediate}), (ii) the substrate edge and intermediate temperature differential (ΔT_{EI}), and/or (iii) the substrate center and intermediate temperature differential (ΔT_{CI}) at desired levels and/or within desired ranges. In this manner, relatively uniform temperatures and/or desired temperature gradients can be maintained on the substrate 2 during the layer forming, deposition, and/or other processing Steps S1410.

During the initial controlled cooling process S1412 (from temperature T5 to T6 at temperature ramping rate R4, which may be about −5° C./second or less on average), the substrate 2 is still at high temperatures (e.g., above 1100° C.), at least when cooling begins. During this time period, the potential for crystal defects remains high. During this initial controlled cooling process S1412, the substrate temperatures will continue to be measured optically by pyrometer 110 (substrate center) and pyrometer 404 (substrate edge) and the edge offset temperature EO will continue to be determined. Further, the controller 114 will control heater elements within the first upper heating zone 410 and the second upper heating zone 412 using the optical temperatures measured to set and maintain the edge offset temperature EO at a desired level (a desired set point) and within a desired range of that set point (e.g., EO may be set at +2° C. with an acceptable range of ±1.5° C.). Additionally, during this initial controlled cooling process S1412, the controller 114 may use optical temperature data measured by pyrometers 110, 402, and 404 to control heater elements within the first upper heating zone 410, the second upper heating zone 412, and/or the third upper heating zone 414 to set and maintain one or more of: (i) the intermediate substrate temperature (T_{Intermediate}), (ii) the substrate edge and intermediate temperature differential (ΔT_{EI}), and/or (iii) the substrate center and intermediate temperature differential (ΔT_{CI}) at desired levels and/or within desired ranges. In this manner, relatively uniform temperatures and desired temperature gradients can be maintained on the substrate 2 during the initial controlled cooling process S1412.

FIG. 15 provides a flow chart of an example temperature control process 1500 in accordance with some aspects of this technology. While FIG. 15 shows a process for measuring and controlling substrate edge temperature (T_{Edge}) and substrate center temperature (T_{Center}) and for determining and controlling the edge offset temperature (EO), similar processes could be used to measure and control the substrate intermediate temperature (T_{Intermediate}) and/or for determining and controlling the substrate edge and intermediate temperature differential (ΔT_{EI}), and/or the substrate center and intermediate temperature differential (ΔT_{CI}) during substrate processing. Also, such processes could be used for measuring, determining, and/or controlling substrate edge temperature (T_{Edge}), substrate center temperature (T_{Center}), edge offset temperature (EO), substrate intermediate temperature (T_{Intermediate}), substrate edge and intermediate temperature differential (ΔT_{EI}), and/or substrate center and intermediate temperature differential (ΔT_{CI}) during any one or more of the substrate processing method steps S1404, S1406, S1408, S1410, and/or S1412 discussed above.

As shown in the example temperature control process 1500 of FIG. 15, the substrate edge temperature T_{Edge} is measured in Step S1502 and the substrate center temperature T_{Center} is measured in Step S1504. Then, the edge offset temperature EO is determined (e.g., calculated) at Step S1506 (EO=(T_{Edge})−(T_{Center})). In the next Step S1508, this temperature control process 1500 determines whether the edge offset temperature EO is within a desired or predetermined range for this substrate processing method step (e.g., one of S1404, S1406, S1408, S1410, and/or S1412 discussed above). If “no,” the controller 114 throttles individual heating elements, e.g., in one or more of the first upper heating zone 410 and/or the second upper heating zone 412 (Step S1510) to heat or cool that zone so the edge offset temperature moves toward the desired range. The process then returns to Step S1502, and the temperature measuring and control processes continue and repeat.

If the edge offset temperature EO is within the desired range at Step 1508 (answer “yes”), then at Step S1512, the temperature control process 1500 determines whether the substrate 2 has reached one or more target temperatures (or set points) for this particular part of the overall substrate processing method. Thus, at Step S1512, the temperature control process 1500 may determine one or more of: (i) whether the substrate edge temperature T_{Edge} has reached its set point (or is within a predetermined range of the set point) for this particular part of the overall substrate processing method; (ii) whether the substrate center temperature T_{Center} has reached its set point (or is within a predetermined range of the set point) for this particular part of the overall substrate processing method; and/or (iii) whether the edge offset temperature EO has reached its set point (or is within a predetermined range of the set point) for this particular part of the overall substrate processing method. If not all desired set points or target temperatures have been attained at Step S1512 (answer “no”), the controller 114 throttles individual heating elements, e.g., in one or more of the first upper heating zone 410 and/or the second upper heating zone 412, to heat or cool the substrate 2 in the manner needed to move the temperature(s) toward the target(s) or set point(s) (Step S1514). Then the process returns to Step S1502, and the temperature measuring and control processes continue and repeat.

If the substrate temperature target(s) or set point(s) have been reached (answer “yes” at S1512), the temperature control process 1500 then determines whether the overall substrate processing method step (e.g., one of process steps S1404, S1406, S1408, S1410, or S1412 discussed above) is complete at Step S1516. If “no,” the process returns to Step S1502, and the temperature measuring and control processes continue and repeat. If the overall substrate processing method step (e.g., one of process steps S1404, S1406, S1408, S1410, or S1412 discussed above) is complete at Step S1516 (answer “yes”), the temperature control process 1500 then will move on to the next overall substrate processing method step (e.g., one of process steps S1406, S1408, S1410, S1412, or S1414 discussed above) at Step S1518.

In some examples of this technology, the temperature control process 1500 of FIG. 15 may include additional steps, e.g., a step of measuring the substrate intermediate temperature (T_{Intermediate}), a step of determining the substrate edge and intermediate temperature differential (ΔT_{EI}), a step of determining the substrate center and intermediate temperature differential (ΔT_{CI}), and/or steps of adjusting and/or controlling one or more of the substrate intermediate temperature (T_{Intermediate}), the substrate edge and intermediate temperature differential (ΔT_{EI}), and/or the substrate center and intermediate temperature differential (ΔT_{CI}). Such measurement and control of these parameters may be accomplished using similar steps to those shown in FIG. 15 (e.g., measuring steps S1502 and S1504, determining step S1506, and control steps S1508-S1516). Individual heater elements in an intermediate upper heating zone (the third upper heating zone 414) may be controlled by controller 114 during such processes to enable control of the substrate intermediate temperature. Alternatively, in some substrate processing methods, controller 114 may use separate processes (akin to temperature control process 1500), e.g., different routines or sub-routines, for determining and controlling the substrate edge and intermediate temperature differential (ΔT_{EI}) and/or the substrate center and intermediate temperature differential (ΔT_{CI}).

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A substrate processing method, comprising:
seating a substrate on a substrate support;
measuring a center substrate temperature using a first pyrometer configured to optically measure temperature of the substrate at a center location of the substrate;
measuring an edge substrate temperature using a second pyrometer configured to optically measure temperature of the substrate at an edge location of the substrate;
determining an edge offset temperature between the edge substrate temperature and the center substrate temperature;
during a first temperature ramping step, increasing substrate temperature from a first temperature to a second temperature at a first fast temperature ramping rate;
during a second temperature ramping step, increasing substrate temperature from the second temperature to a third temperature at a second fast temperature ramping rate, wherein the second fast temperature ramping rate is the same as or different from the first fast temperature ramping rate, and wherein during the second temperature ramping step, heating of the substrate is controlled to place and/or hold the edge offset temperature within a first predetermined range; and
during a third temperature ramping step, increasing substrate temperature from the third temperature to a fourth temperature at a slow temperature ramping rate, wherein during the third temperature ramping step, heating of the substrate is controlled to place and/or hold the edge offset temperature within a second predetermined range, wherein the second predetermined range is the same as or different from the first predetermined range.

2. The substrate processing method according to claim 1, wherein after the third temperature ramping step, the method further comprises:
flowing a material layer precursor across the substrate; and
depositing a material layer onto the substrate using the material layer precursor,
wherein during the flowing and depositing, heating of the substrate is controlled to place and/or hold the edge offset temperature within a third predetermined range, and wherein the third predetermined range is the same as or different from the second predetermined range.

3. The substrate processing method according to claim 2, further comprising:
measuring an intermediate substrate temperature using a third pyrometer configured to optically measure temperature of the substrate at an intermediate location on the substrate between the center location and the edge location, wherein during the depositing step, heating of the substrate is controlled to place and/or hold the intermediate substrate temperature within a first predetermined temperature range from the center substrate temperature.

4. The substrate processing method according to claim 2, further comprising:
measuring an intermediate substrate temperature using a third pyrometer configured to optically measure temperature of the substrate at an intermediate location on the substrate between the center location and the edge location, wherein during the depositing step, heating of the substrate is controlled to place and/or hold the intermediate substrate temperature within a first predetermined temperature range from the edge substrate temperature.

5. The substrate processing method according to claim 2, further comprising:
cooling the substrate to a first cooled temperature, wherein during the cooling, heating of the substrate is controlled: (i) to place and/or hold the edge offset temperature within a controlled temperature differential range, and (ii) to cool the substrate at a cooling rate that is slower than a free fall cooling rate.

6. The substrate processing method according to claim 5, further comprising:
after the substrate reaches the first cooled temperature, further cooling the substrate using a free fall cooling technique.

7. The substrate processing method according to claim 1, further comprising:
cooling the substrate to a first cooled temperature, wherein during the cooling, heating of the substrate is controlled: (i) to place and/or hold the edge offset temperature within a controlled temperature differential range, and (ii) to cool the substrate at a cooling rate that is slower than a free fall cooling rate.

8. The substrate processing method according to claim 7, further comprising:
after the substrate reaches the first cooled temperature, further cooling the substrate using a free fall cooling technique.

9. The substrate processing method according to claim 1, wherein during the first temperature ramping step, heating of the substrate is controlled to place and/or hold the edge offset temperature within an initial temperature differential range, wherein the initial temperature differential range is wider than the first predetermined range used in the second temperature ramping step.

10. The substrate processing method according to claim 1, further comprising:
measuring an intermediate substrate temperature using a third pyrometer configured to optically measure temperature of the substrate at an intermediate location on the substrate between the center location and the edge location, wherein during the second temperature ramping step, heating of the substrate is controlled to place and/or hold the intermediate substrate temperature within a first predetermined temperature range from the center substrate temperature.

11. The substrate processing method according to claim 10, wherein during the third temperature ramping step, heating of the substrate is controlled to place and/or hold the intermediate substrate temperature within a second predetermined temperature range from the center substrate temperature.

12. The substrate processing method according to claim 1, further comprising:
measuring an intermediate substrate temperature using a third pyrometer configured to optically measure temperature of the substrate at an intermediate location on the substrate between the center location and the edge location, wherein during the third temperature ramping step, heating of the substrate is controlled to place and/or hold the intermediate substrate temperature within a first predetermined temperature range from the center substrate temperature.

13. The substrate processing method according to claim 1, further comprising:
measuring an intermediate substrate temperature using a third pyrometer configured to optically measure temperature of the substrate at an intermediate location on the substrate between the center location and the edge location, wherein during the second temperature ramping step, heating of the substrate is controlled to place and/or hold the intermediate substrate temperature within a first predetermined temperature range from the edge substrate temperature.

14. The substrate processing method according to claim 13, wherein during the third temperature ramping step, heating of the substrate is controlled to place and/or hold the intermediate substrate temperature within a second predetermined temperature range from the edge substrate temperature.

15. The substrate processing method according to claim 1, further comprising:
measuring an intermediate substrate temperature using a third pyrometer configured to optically measure temperature of the substrate at an intermediate location on the substrate between the center location and the edge location, wherein during the third temperature ramping step, heating of the substrate is controlled to place and/or hold the intermediate substrate temperature within a first predetermined temperature range from the edge substrate temperature.

16. A substrate processing method, comprising:
seating a substrate on a substrate support located in a chamber arrangement, wherein the chamber arrangement includes: (i) a chamber body having an upper wall and a lower wall, (ii) the substrate support arranged within an interior of the chamber body and supported for rotation about a rotation axis, (iii) an upper heater element array supported above the upper wall of the chamber body, wherein heater elements of the upper heater element array include a first heating zone and a second heating zone, (iv) a first pyrometer supported above the upper heater element array, optically coupled to the interior of the chamber body, and configured to optically measure a center substrate temperature, (v) a second pyrometer supported above the upper heater element array, optically coupled to the interior of the chamber body, and configured to optically measure an edge substrate temperature, and (vi) a control system to control power applied to the heater elements of the upper heater element array;
measuring the center substrate temperature of the substrate using the first pyrometer;
measuring the edge substrate temperature of the substrate using the second pyrometer;
determining an edge offset temperature between the edge substrate temperature and the center substrate temperature;
during a first temperature ramping step, increasing substrate temperature from a first temperature to a second temperature at a first fast temperature ramping rate;
during a second temperature ramping step, increasing substrate temperature from the second temperature to a third temperature at a second fast temperature ramping rate, wherein the second fast temperature ramping rate is the same as or different from the first fast temperature ramping rate, and wherein during the second temperature ramping step, the control system controls power applied to one or more heater elements in the first heating zone and one or more heater elements in the second heating zone to place and/or hold the edge offset temperature within a first predetermined range; and
during a third temperature ramping step, increasing substrate temperature from the third temperature to a fourth temperature at a slow temperature ramping rate, wherein during the third temperature ramping step, the control system controls power applied to one or more heater elements in the first heating zone and one or more heater elements in the second heating zone to place and/or hold the edge offset temperature within a second predetermined range, and wherein the second predetermined range is the same as or different from the first predetermined range.

17. The substrate processing method according to claim 16, wherein after the third temperature ramping step, the method further comprises:
flowing a material layer precursor across the substrate; and
depositing a material layer onto the substrate using the material layer precursor,
wherein during the flowing and depositing, the control system controls power applied to one or more heater elements in the first heating zone and one or more heater elements in the second heating zone to place and/or hold the edge offset temperature within a third predetermined range, and wherein the third predetermined range is the same as or different from the second predetermined range.

18. The substrate processing method according to claim 17, wherein the chamber arrangement further includes a third pyrometer supported above the upper heater element array, optically coupled to the interior of the chamber body, and configured to optically measure an intermediate substrate temperature, wherein heater elements of the upper heater element array further include a third heating zone located between the first heating zone and the second heating zone, and wherein the method further includes:
measuring the intermediate substrate temperature using the third pyrometer, wherein during the second temperature ramping step, the control system controls power applied to one or more heater elements in the third heating zone and/or one or more heater elements in the first heating zone to place and/or hold the intermediate substrate temperature within a first predetermined temperature range from the center substrate temperature.

19. The substrate processing method according to claim 17, wherein the chamber arrangement further includes a third pyrometer supported above the upper heater element array, optically coupled to the interior of the chamber body, and configured to optically measure an intermediate substrate temperature, wherein heater elements of the upper heater element array further include a third heating zone located between the first heating zone and the second heating zone, and wherein the method further includes:
measuring the intermediate substrate temperature using the third pyrometer, wherein during the second temperature ramping step, the control system controls power applied to one or more heater elements in the third heating zone and/or one or more heater elements in the second heating zone to place and/or hold the intermediate substrate temperature within a first predetermined temperature range from the edge substrate temperature.

20. The substrate processing method according to claim 17, further comprising:
cooling the substrate to a first cooled temperature, wherein the control system controls power applied to one or more heater elements in the first heating zone and one or more heater elements in the second heating zone: (i) to place and/or hold the edge offset temperature within a controlled temperature differential range, and (ii) to cool the substrate at a cooling rate that is slower than a free fall cooling rate.

21. The substrate processing method according to claim 20, further comprising:
after the substrate reaches the first cooled temperature, further cooling the substrate using a free fall cooling technique.

22. The substrate processing method according to claim 16, further comprising:
cooling the substrate to a first cooled temperature, wherein the control system controls power applied to one or more heater elements in the first heating zone and one or more heater elements in the second heating zone: (i) to place and/or hold the edge offset temperature within a controlled temperature differential range, and (ii) to cool the substrate at a cooling rate that is slower than a free fall cooling rate.

23. The substrate processing method according to claim 22, further comprising:
after the substrate reaches the first cooled temperature, further cooling the substrate using a free fall cooling technique.

24. The substrate processing method according to claim 16, wherein during the first temperature ramping step, the control system controls power applied to one or more heater elements in the first heating zone and/or one or more heater elements in the second heating zone to place and/or hold the edge offset temperature within an initial temperature differential range, wherein the initial temperature differential range is wider than the first predetermined range used in the second temperature ramping step.
